(19) United States
(12) Patent Application Publication
(10) Pub. No.: US 2025/0192807 A1
(43) Pub. Date: Jun. 12, 2025

(54) METHOD AND DEVICE FOR TRANSMITTING INFORMATION, AND METHOD AND DEVICE FOR RECEIVING INFORMATION

(71) Applicants: LG ELECTRONICS INC., Seoul (KR); KOREA ADVANCED INSTITUTE OF SCIENCE AND TECHNOLOGY, Daejeon (KR)

(72) Inventors: Bonghoe KIM, Seoul (KR); Jeongseok HA, Seoul (KR); Seokju HAN, Seoul (KR)

(73) Assignees: LG ELECTRONICS INC., Seoul (KR); KOREA ADVANCED INSTITUTE OF SCIENCE AND TECHNOLOGY, Daejeon (KR)

(21) Appl. No.: 18/711,041

(22) PCT Filed: Nov. 17, 2021
(86) PCT No.: PCT/KR2021/016863

§ 371 Date: Nov. 11, 2024

(51) Int. Cl. H03M 13/13; H03M 13/00; H03M 13/09

(52) U.S. Cl. CPC H03M 13/13; H03M 13/09; H03M 13/6362

(57) ABSTRACT

The present method relates to a method by which a device transmits a signal in a communication system and to a device therefor, the method comprising the steps of: generating a first encoded bit sequence from an information bit sequence on the basis of a polar code; generating a second encoded bit sequence by puncturing the first encoded bit sequence, on the basis of a code rate; and transmitting the second encoded bit sequence, wherein the first encoded bit sequence is processed on the basis of a proposed puncturing pattern, and the puncturing pattern satisfies a nested property.

### CROSS-REFERENCE TO RELATED APPLICATION(S)

This application is the National Stage filing under 35 U.S.C. 371 of International Application No. PCT/KR2021/016863, filed on Nov. 17, 2021, the contents of which are all incorporated by reference herein in its entirety.

### TECHNICAL FIELD

The disclosure relates to a communication system, and particularly, to a method and apparatus for transmitting/receiving information. More particularly, the disclosure relates to a rate-compatible polar coding method using a puncturing technique and an apparatus using the same.

### BACKGROUND ART

Polar codes, which are known as channel capacity achieving codes on discrete memoryless symmetric channels, have received considerable attention as a core technology in the fifth-generation (5G) mobile communication standard. The polar codes are designed based on channel polarization, which is obtained by repeated concatenation of short kernel codes. Based on the reliability of polarized bit channels, the channel polarization allows to transmit information bits over reliable channels and configure frozen bits, which are shared by a transmitter and receiver, on less reliable channels. The polar codes are decoded by a recursive successive cancellation (SC) decoder, list SC decoder, or belief propagation decoder.

### SUMMARY

An object of the disclosure is to provide a method of increasing the performance of a rate-compatible polar code, a method of transmitting and receiving a signal using the same, and an apparatus therefor.

It will be appreciated by persons skilled in the art that the objects that could be achieved with the various embodiments of the present disclosure are not limited to what has been particularly described hereinabove and the above and other objects that the various embodiments of the present disclosure could achieve will be more clearly understood from the following detailed description.

In a first aspect of the disclosure, a method of transmitting a signal by a transmission device in a communication system is provided, including generating a first encoded bit sequence from an information bit sequence based on a polar code, generating a second encoded bit sequence by puncturing the first encoded bit sequence based on a code rate, and transmitting the second encoded bit sequence. The first encoded bit sequence is implemented based on a puncturing pattern including the structure of Table 1 below, and the puncturing pattern satisfies a nested property.

In a second aspect of the disclosure, a transmission device used in a communication system is provided, including at least one radio frequency (RF) unit, at least one processor, and at least one computer memory operably connected to the at least one processor, and when executed, causing the at least one processor to perform operations. The operations include generating a first encoded bit sequence from an information bit sequence, based on a polar code, generating a second encoded bit sequence by puncturing the first encoded bit sequence based on a code rate, and transmitting the second encoded bit sequence. The first encoded bit sequence is implemented based on a puncturing pattern including the structure of Table 1 below, and the puncturing pattern satisfies a nested property.

In a third aspect of the disclosure, an apparatus used in a transmission device is provided, including at least one processor, and at least one computer memory operably connected to the at least one processor, and when executed, causing the at least one processor to perform operations. The operations include generating a first encoded bit sequence from an information bit sequence, based on a polar code, generating a second encoded bit sequence by puncturing the first encoded bit sequence based on a code rate, and transmitting the second encoded bit sequence. The first encoded bit sequence is implemented based on a puncturing pattern including the structure of Table 1 below, and the puncturing pattern satisfies a nested property.

In a fourth aspect of the disclosure, a computer-readable storage medium including at least one computer program which when executed, causes at least one processor to perform operations is provided. The operations include generating a first encoded bit sequence from an information bit sequence, based on a polar code, generating a second encoded bit sequence by puncturing the first encoded bit sequence based on a code rate, and transmitting the second encoded bit sequence. The first encoded bit sequence is implemented based on a puncturing pattern including the structure of Table 1 below, and the puncturing pattern satisfies a nested property.

TABLE 1

| | Puncturing pattern (number of punctured bits: 122) |
|---|---|
| (512, 256) | 1, 2, 3, 4, 5, 6, 7, 8, 9, 10, 11, 12, 13, 14, 15, 16, 17, 18, 19, 20, 21, 22, 23, 24, 25, |
| Polar code | 26, 27, 29, 33, 34, 35, 36, 37, 38, 39, 41, 42, 43, 45, 49, 50, 51, 53, 65, 66, 67, 68, 69, |
| | 70, 71, 73, 74, 75, 77, 81, 82, 97, 129, 130, 131, 132, 133, 134, 137, 145, 161, |
| | 257, 258, 259, 260, 261, 262, 265, 273, 289, 32, 28, 30, 31, 40, 44, 46, 52, 72, |
| | 47, 54, 55, 76, 78, 79, 48, 88, 136, 58, 84, 86, 90, 59, 61, 144, 104, 180, 122, 87, |
| | 100, 102, 103, 106, 114, 200, 57, 83, 85, 89, 98, 99, 101, 135, 138, 139, 141, 146 |

Preferably, the puncturing pattern may include the following.

TABLE 2

| | Puncturing pattern (number of punctured bits: 164) |
|---|---|
| (512, 256) | 1, 2, 3, 4, 5, 6, 7, 8, 9, 10, 11, 12, 13, 14, 15, 16, 17, 18, 19, 20, 21, 22, 23, 24, 25, |
| Polar code | 26, 27, 29, 33, 34, 35, 36, 37, 38, 39, 41, 42, 43, 45, 49, 50, 51, 53, 65, 66, 67, 68, |
| | 69, 70, 71, 73, 74, 75, 77, 81, 82, 97, 129, 130, 131, 132, 133, 134, 137, 145, 161, |
| | 257, 258, 259, 260, 261, 262, 265, 273, 289, 32, 28, 30, 31, 40, 44, 46, 52, 72, |
| | 47, 54, 55, 76, 78, 79, 48, 88, 136, 58, 84, 86, 90, 59, 61, 144, 104, 180, 122, 87, |
| | 100, 102, 103, 106, 114, 200, 57, 83, 85, 89, 98, 99, 101, 135, 138, 139, 141, |
| | 146, 147, 149, 153, 162, 163, 165, 63, 158, 92, 110, 140, 142, 148, 164, 91, 93, |
| | 119, 105, 113, 150, 143, 151, 154, 155, 157, 280, 229, 194, 195, 197, 172, 264, |
| | 299, 309, 333, 276, 272, 193, 263, 266, 267, 269 |

Preferably, the puncturing pattern may include the following.

TABLE 3

| | Puncturing pattern (number of punctured bits: 205) |
|---|---|
| (512, 256) | 1, 2, 3, 4, 5, 6, 7, 8, 9, 10, 11, 12, 13, 14, 15, 16, 17, 18, 19, 20, 21, 22, 23, 24, 25, |
| Polar code | 26, 27, 29, 33, 34, 35, 36, 37, 38, 39, 41, 42, 43, 45, 49, 50, 51, 53, 65, 66, 67, 68, |
| | 69, 70, 71, 73, 74, 75, 77, 81, 82, 97, 129, 130, 131, 132, 133, 134, 137, 145, 161, |
| | 257, 258, 259, 260, 261, 262, 265, 273, 289, 32, 28, 30, 31, 40, 44, 46, 52, 72, |
| | 47, 54, 55, 76, 78, 79, 48, 88, 136, 58, 84, 86, 90, 59, 61, 144, 104, 180, 122, 87, |
| | 100, 102, 103, 106, 114, 200, 57, 83, 85, 89, 98, 99, 101, 135, 138, 139, 141, |
| | 146, 147, 149, 153, 162, 163, 165, 63, 158, 92, 110, 140, 142, 148, 164, 91, 93, |
| | 119, 105, 113, 150, 143, 151, 154, 155, 157, 280, 229, 194, 195, 197, 172, 264, |
| | 299, 309, 333, 276, 272, 193, 263, 266, 267, 269, 274, 115, 169, 177, 159, |
| | 118, 170, 108, 270, 95, 109, 331, 279, 275, 277, 290, 291, 293, 166, 329, 179, |
| | 278, 298, 305, 196, 199, 217, 174, 60, 173, 324, 283, 390, 321, 209, 152, 117, |
| | 198, 295, 201, 322 |

According to embodiment(s) of the disclosure, the performance of a rate-compatible polar code may be increased. Further, a method and apparatus using the same may be provided.

The effects of the invention are not limited to those mentioned above, and other effects not mentioned will become apparent to one having ordinary knowledge in the art to which the invention belongs from the following detailed description of the invention.

### BRIEF DESCRIPTION OF THE DRAWINGS

The accompanying drawings, which are incorporated as part of the detailed description to facilitate an understanding of the disclosure, provide examples of the invention and, together with the detailed description, illustrate the technical ideas of the invention.

FIG. 1 is a block diagram for a polar code encoder.

FIG. 2 illustrates the concept of channel combining and channel splitting for channel polarization.

FIG. 3 illustrates N-th level channel combining for a polar code.

FIG. 4 illustrates the concept of selecting position(s) to which information bit(s) are to be allocated in polar codes.

FIG. 5 illustrates exemplary puncturing and information bit allocation for a polar code.

FIGS. 6 to 8 are diagrams illustrating restoration scores.

FIG. 9 illustrates an exemplary signal transmission process according to an embodiment of the disclosure.

FIGS. 10 to 13 illustrate exemplary simulation results of a polar code according to the disclosure.

FIG. 14 illustrates an example of a frame structure.

FIG. 15 illustrates an exemplary encoding process and decoding process in a legacy LTE system.

FIGS. 16 to 19 illustrate a communication system 1 and wireless devices applicable to the disclosure.

### DETAILED DESCRIPTION

Reference will now be made in detail to the exemplary examples of the present invention, examples of which are illustrated in the accompanying drawings. The detailed description, which will be given below with reference to the accompanying drawings, is intended to explain exemplary examples of the present invention, rather than to show the only examples that can be implemented according to the invention. The following detailed description includes specific details in order to provide a thorough understanding of the present invention. However, it will be apparent to those skilled in the art that the present invention may be practiced without such specific details.

In some instances, known structures and devices are omitted or are shown in block diagram form, focusing on important features of the structures and devices, so as not to obscure the concept of the present invention. The same reference numbers will be used throughout this specification to refer to the same or like parts.

The following techniques, apparatuses, and systems may be applied to a variety of wireless multiple access systems. Examples of the multiple access systems include a code division multiple access (CDMA) system, a frequency division multiple access (FDMA) system, a time division multiple access (TDMA) system, an orthogonal frequency division multiple access (OFDMA) system, a single carrier frequency division multiple access (SC-FDMA) system, and a multicarrier frequency division multiple access (MC-FDMA) system. CDMA may be embodied through radio technology such as universal terrestrial radio access (UTRA) or CDMA2000. TDMA may be embodied through radio technology such as global system for mobile communications (GSM), general packet radio service (GPRS), or enhanced data rates for GSM evolution (EDGE). OFDMA may be embodied through radio technology such as institute of electrical and electronics engineers (IEEE) 802.11 (Wi-Fi), IEEE 802.16 (WiMAX), IEEE 802.20, or evolved UTRA (E-UTRA). UTRA is a part of a universal mobile telecommunications system (UMTS). 3rd generation partnership project (3GPP) long term evolution (LTE) is a part of evolved UMTS (E-UMTS) using E-UTRA. 3GPP LTE employs OFDMA in DL and SC-FDMA in UL. LTE-advanced (LTE-A) is an evolved version of 3GPP LTE. For convenience of description, it is assumed that the present invention is applied to 3GPP based communication system, e.g. LTE/LTE-A, NR. However, the technical features of the present invention are not limited thereto. For example, although the following detailed description is given based on a mobile communication system corresponding to a 3GPP LTE/LTE-A/NR system, aspects of the present invention that are not specific to 3GPP LTE/LTE-A/NR are applicable to other mobile communication systems.

In examples of the present invention described below, the expression that a device “assumes” may mean that a subject which transmits a channel transmits the channel in accordance with the corresponding “assumption”. This may also mean that a subject which receives the channel receives or decodes the channel in a form conforming to the “assumption”, on the assumption that the channel has been transmitted according to the “assumption”.

In the present invention, a user equipment (UE) may be a fixed or mobile device. Examples of the UE include various devices that transmit and receive user data and/or various kinds of control information to and from a base station (BS). The UE may be referred to as a terminal equipment (TE), a mobile station (MS), a mobile terminal (MT), a user terminal (UT), a subscriber station (SS), a wireless device, a personal digital assistant (PDA), a wireless modem, a handheld device, etc. In addition, in the present invention, a BS generally refers to a fixed station that performs communication with a UE and/or another BS, and exchanges various kinds of data and control information with the UE and another BS. The BS may be referred to as an advanced base station (ABS), a node-B (NB), an evolved node-B (eNB), a base transceiver system (BTS), an access point (AP), a processing server (PS), etc. Particularly, a BS of a UTRAN is referred to as a Node-B, a BS of an E-UTRAN is referred to as an eNB, and a BS of a new radio access technology network is referred to as an gNB. Herein, for convenience of description, a base station will be referred to as a BS regardless of type or version of communication technology.

In the present invention, a node refers to a fixed point capable of transmitting/receiving a radio signal through communication with a UE. Various types of BSs may be used as nodes irrespective of the terms thereof. For example, a BS, a node B (NB), an e-node B (eNB), a pico-cell eNB (PeNB), a home eNB (HeNB), a relay, a repeater, etc. may be a node. In addition, the node may not be a BS. For example, the node may be a radio remote head (RRH) or a radio remote unit (RRU). The RRH or RRU generally has a lower power level than a power level of a BS. Since the RRH or RRU (hereinafter, RRH/RRU) is generally connected to the BS through a dedicated line such as an optical cable, cooperative communication between RRH/RRU and the BS can be smoothly performed in comparison with cooperative communication between BSs connected by a radio line. At least one antenna is installed per node. The antenna may mean a physical antenna or mean an antenna port or a virtual antenna.

In the present invention, a cell refers to a prescribed geographical area to which one or more nodes provide a communication service. Accordingly, in the present invention, communicating with a specific cell may mean communicating with a BS or a node which provides a communication service to the specific cell. In addition, a DL/UL signal of a specific cell refers to a DL/UL signal from/to a BS or a node which provides a communication service to the specific cell. A node providing UL/DL communication services to a UE is called a serving node and a cell to which UL/DL communication services are provided by the serving node is especially called a serving cell. Furthermore, channel status/quality of a specific cell refers to channel status/quality of a channel or communication link formed between a BS or node which provides a communication service to the specific cell and a UE. In the 3GPP based communication system, the UE may measure DL channel state received from a specific node using cell-specific reference signal(s) (CRS(s)) transmitted on a CRS resource and/or channel state information reference signal(s) (CSI-RS(s)) transmitted on a CSI-RS resource, allocated by antenna port(s) of the specific node to the specific node.

Meanwhile, a 3GPP based communication system uses the concept of a cell in order to manage radio resources and a cell associated with the radio resources is distinguished from a cell of a geographic region.

A “cell” of a geographic region may be understood as coverage within which a node can provide service using a carrier and a “cell” of a radio resource is associated with bandwidth (BW) which is a frequency range configured by the carrier. Since DL coverage, which is a range within which the node is capable of transmitting a valid signal, and UL coverage, which is a range within which the node is capable of receiving the valid signal from the UE, depends upon a carrier carrying the signal, the coverage of the node may be associated with coverage of the “cell” of a radio resource used by the node. Accordingly, the term “cell” may be used to indicate service coverage of the node sometimes, a radio resource at other times, or a range that a signal using a radio resource can reach with valid strength at other times.

Meanwhile, the 3GPP communication standards use the concept of a cell to manage radio resources. The “cell” associated with the radio resources is defined by combination of downlink resources and uplink resources, that is, combination of DL CC and UL CC. The cell may be configured by downlink resources only, or may be configured by downlink resources and uplink resources. If carrier aggregation is supported, linkage between a carrier frequency of the downlink resources (or DL CC) and a carrier frequency of the uplink resources (or UL CC) may be indicated by system information. For example, combination of the DL resources and the UL resources may be indicated by linkage of system information block type 2 (SIB2). The carrier frequency may be the same as a center frequency of each cell or CC. A cell operating on a primary frequency may be referred to as a primary cell (Pcell) or PCC, and a cell operating on a secondary frequency may be referred to as a secondary cell (Scell) or SCC. The carrier corresponding to the Pcell on downlink will be referred to as a downlink primary CC (DL PCC), and the carrier corresponding to the Pcell on uplink will be referred to as an uplink primary CC (UL PCC). A Scell means a cell that may be configured after completion of radio resource control (RRC) connection establishment and used to provide additional radio resources. The Scell may form a set of serving cells for the UE together with the Pcell in accordance with capabilities of the UE. The carrier corresponding to the Scell on the downlink will be referred to as downlink secondary CC (DL SCC), and the carrier corresponding to the Scell on the uplink will be referred to as uplink secondary CC (UL SCC). Although the UE is in RRC-CONNECTED state, if it is not configured by carrier aggregation or does not support carrier aggregation, a single serving cell configured by the Pcell only exists.

3GPP based communication standards define DL physical channels corresponding to resource elements carrying information derived from a higher layer and DL physical signals corresponding to resource elements which are used by a physical layer but which do not carry information derived from a higher layer. For example, a physical downlink shared channel (PDSCH), a physical broadcast channel (PBCH), a physical multicast channel (PMCH), a physical control format indicator channel (PCFICH), a physical downlink control channel (PDCCH), and a physical hybrid ARQ indicator channel (PHICH) are defined as the DL physical channels, and a reference signal and a synchronization signal are defined as the DL physical signals. A reference signal (RS), also called a pilot, refers to a special waveform of a predefined signal known to both a BS and a UE. For example, a cell-specific RS (CRS), a UE-specific RS (UE-RS), a positioning RS (PRS), and channel state information RS (CSI-RS) may be defined as DL RSs. Meanwhile, the 3GPP based communication standards define UL physical channels corresponding to resource elements carrying information derived from a higher layer and UL physical signals corresponding to resource elements which are used by a physical layer but which do not carry information derived from a higher layer. For example, a physical uplink shared channel (PUSCH), a physical uplink control channel (PUCCH), and a physical random access channel (PRACH) are defined as the UL physical channels, and a demodulation reference signal (DM RS) for a UL control/data signal and a sounding reference signal (SRS) used for UL channel measurement are defined as the UL physical signals.

In the present invention, a physical downlink control channel (PDCCH), a physical control format indicator channel (PCFICH), a physical hybrid automatic retransmit request indicator channel (PHICH), and a physical downlink shared channel (PDSCH) refer to a set of time-frequency resources or resource elements (REs) carrying downlink control information (DCI), a set of time-frequency resources or REs carrying a control format indicator (CFI), a set of time-frequency resources or REs carrying downlink acknowledgement (ACK)/negative ACK (HACK), and a set of time-frequency resources or REs carrying downlink data, respectively. In addition, a physical uplink control channel (PUCCH), a physical uplink shared channel (PUSCH) and a physical random access channel (PRACH) refer to a set of time-frequency resources or REs carrying uplink control information (UCI), a set of time-frequency resources or REs carrying uplink data and a set of time-frequency resources or REs carrying random access signals, respectively. In the present invention, in particular, a time-frequency resource or RE that is assigned to or belongs to PDCCH/PCFICH/PHICH/PDSCH/PUCCH/PUSCH/PRACH is referred to as PDCCH/PCFICH/PHICH/PDSCH/PUCCH/PUSCH/PRACH RE or PDCCH/PCFICH/PHICH/PDSCH/PUCCH/PUSCH/PRACH time-frequency resource, respectively. Therefore, in the present invention, PUCCH/PUSCH/PRACH transmission of a UE is conceptually identical to UCI/uplink data/random access signal transmission on PUSCH/PUCCH/PRACH, respectively. In addition, PDCCH/PCFICH/PHICH/PDSCH transmission of a BS is conceptually identical to downlink data/DCI transmission on PDCCH/PCFICH/PHICH/PDSCH, respectively.

For terms and technologies which are not described in detail in the present invention, reference can be made to the standard document of 3GPP LTE/LTE-A, for example, 3GPP TS 36.211, 3GPP TS 36.212, 3GPP TS 36.213, 3GPP TS 36.321, and 3GPP TS 36.331 and the standard document of 3GPP NR, for example, 3GPP TS 38.211, 3GPP TS 38.212, 3GPP TS 38.213, 3GPP TS 38.214, 3GPP TS 38.300 and 3GPP TS 38.331. In addition, as to polar codes and the principle of encoding and decoding using the polar codes, reference may be made to ‘E. Arikan, “Channel Polarization: A Method for Constructing Capacity-Achieving Codes for Symmetric Binary-Input Memoryless Channels,” in IEEE Transactions on Information Theory, vol. 55, no. 7, pp. 3051-3073, July 2009′.

As more communication devices have demanded higher communication capacity, there has been necessity of enhanced mobile broadband relative to legacy radio access technology (RAT). In addition, massive machine type communication for providing various services irrespective of time and place by connecting a plurality of devices and objects to each other is one main issue to be considered in future-generation communication. Further, a communication system design in which services/UEs sensitive to reliability and latency are considered is under discussion. The introduction of future-generation RAT has been discussed by taking into consideration enhanced mobile broadband communication, massive MTC, ultra-reliable and low-latency communication (URLLC), and the like. In current 3GPP, a study of the future-generation mobile communication system after EPC is being conducted. In the present invention, the corresponding technology is referred to as a new RAT (NR) or 5G RAT, for convenience.

NR provides higher speeds and better coverage than current 4G. NR operates in a high frequency band and is required to offer speeds of up to 1 Gb/s for tens of connections or tens of Mb/s for tens of thousands of connections. To meet requirements of such an NR system, introduction of a more evolved coding scheme than a legacy coding scheme is under discussion. Since data communication arises in an incomplete channel environment, channel coding plays an important role in achieving a higher data rate for fast and error-free communication. A selected channel code needs to provide superior block error ratio (BLER) performance for block lengths and code rates of a specific range. Herein, BLER is defined as the ratio of the number of erroneous received blocks to the total number of sent blocks. In NR, low calculation complexity, low latency, low cost, and higher flexibility are demanded for a coding scheme. Furthermore, reduced energy per bit and improved region efficiency are needed to support a higher data rate. Use examples for NR networks are enhanced mobile broadband (eMBB), massive Internet of things (IoT), and ultra-reliable and low latency communication (URLLC). eMBB covers Internet access with high data rates to enable rich media applications, cloud storage and applications, and augmented reality for entertainment. Massive IoT applications include dense sensor networks for smart homes/buildings, remote health monitoring, and logistics tracking. URLLC covers critical applications that demand ultra-high reliability and low latency, such as industrial automation, driverless vehicles, remote surgery, and smart grids.

Although many coding schemes with high capacity performance at large block lengths are available, many of these coding schemes do not consistently exhibit excellent good performance in a wide range of block lengths and code rates. However, turbo codes, low-density parity check (LPDC) codes, and polar codes show promising BLER performance in a wide range of coding rates and code lengths and hence are considered to be used in the NR system. As demand for various cases such as eMBB, massive IoT, and URLLC has increased, a coding scheme providing greater channel coding efficiency than in turbo codes is needed. In addition, increase in a maximum number of subscribers capable of being accommodated by a channel, i.e., increase in capacity, has been required.

Polar codes are codes providing a new framework capable of solving problems of legacy channel codes and were invented by Arikan at Bilkent University (reference: E. Arikan, “Channel Polarization: A Method for Constructing Capacity-Achieving Codes for Symmetric Binary-Input Memoryless Channels,” in IEEE Transactions on Information Theory, vol. 55, no. 7, pp. 3051-3073, July 2009). Polar codes are the first capacity-achieving codes with low encoding and decoding complexities, which were proven mathematically. Polar codes outperform the turbo codes in large block lengths while no error flow is present. Hereinafter, channel coding using the polar codes is referred to as polar coding.

Polar codes are known as codes capable of achieving the capacity of a given binary discrete memoryless channel. This can be achieved only when a block size is sufficiently large. That is, polar codes are codes capable of achieving the capacity of a channel if the size N of the codes infinitely increases. Polar codes have low encoding and decoding complexity and may be successfully decoded. Polar codes are a sort of linear block error correction codes. Multiple recursive concatenations are basic building blocks for the polar codes and are bases for code construction. Physical conversion of channels in which physical channels are converted into virtual channels occurs and such conversion is based on a plurality of recursive concatenations. If multiple channels are multiplied and accumulated, most of the channels may become better or worse. The idea underlying polar codes is to use good channels. For example, data is sent through good channels at rate 1 and data is sent through bad channels at rate 0. That is, through channel polarization, channels enter a polarized state from a normal state.

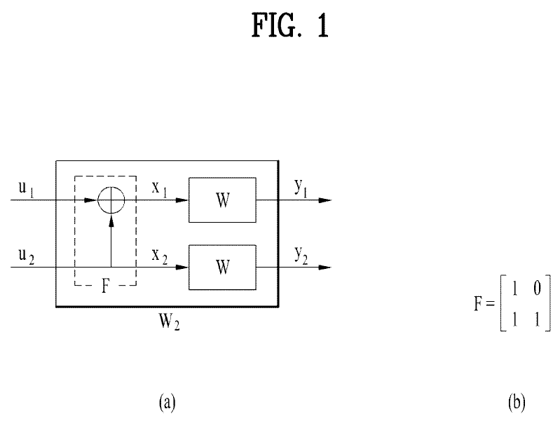

FIG. 1 is a block diagram for a polar code encoder.

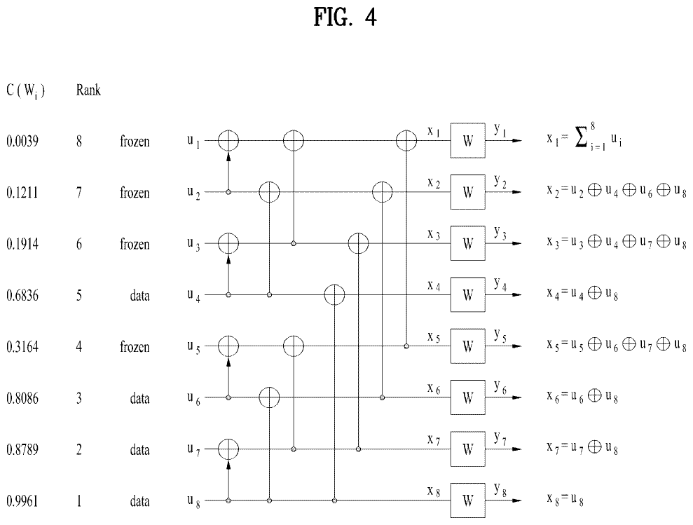

FIG. 1(a) illustrates a base module of a polar code, particularly, first level channel combining for polar coding. In FIG. 4(a), W₂ denotes an entire equivalent channel obtained by combining two binary-input discrete memoryless channels (B-DMCs), Ws. Herein, u₁ and u₂ are binary-input source bits and y₁ and y₂ are output coded bits. Channel combining is a procedure of concatenating the B-DMCs in parallel.

FIG. 1(b) illustrates a base matrix F for the base module. The binary-input source bits u₁ and u₂ input to the base matrix F and the output coded bits x₁ and x₂ of the base matrix F have the following relationship.

$$[ \begin{matrix}{u}_{1} & {u}_{2}\end{matrix} ] [ \begin{matrix}1 & 0 \\ 1 & 1\end{matrix} ] = [ \begin{matrix}{x}_{1} & {x}_{2}\end{matrix} ] \qquad Equation 1$$

The channel W₂ may achieve symmetric capacity I(W) which is a highest rate. In the B-DMC W, symmetric capacity is an important parameter which is used to measure a rate and is a highest rate at which reliable communication can occur over the channel W. The B-DMC may be defined as follows.

$$I ( W ) = {\sum }_{y ∈ Y} {\sum }_{x ∈ X} \frac{1}{2} W ( y \vert x ) log \frac{w ( y \vert x )}{\frac{1}{2} w ( y \vert 0 ) + \frac{1}{2} w ( y \vert 1 )} \qquad Equation 2$$

It is possible to synthesize or create a second set of N binary input channels out of N independent copies of a given B-DMC W and the channels have the properties {W_{N}⁽ⁱ⁾: 1≤i≤N}. If N increases, there is a tendency for a part of the channels to have capacity approximating to 1 and for the remaining channels to have capacity approximating to 0. This is called channel polarization. In other words, channel polarization is a process of creating a second set of N channels {W_{N}⁽ⁱ⁾: 1≤i≤N} using N independent copies of a given B-DMC W. The effect of channel polarization means that, when N increases, all symmetric capacity terms {I(W_{N}⁽ⁱ⁾)} tend towards 0 or 1 for all except a vanishing fraction of indexes i. In other words, the concept behind channel polarization in the polar codes is transforming N copies (i.e., N transmissions) of a channel having a symmetric capacity of I(W) (e.g., additive white Gaussian noise channel) into extreme channels of capacity close to 1 or 0. Among the N channels, an I(W) fraction will be perfect channels and an 1−I(W) fraction will be completely noise channels. Then, information bits are transmitted only through good channels and bits input to the other channels are frozen to 1 or 0. The amount of channel polarization increases along with a block length. Channel polarization consists of two phases: channel combining phase and channel splitting phase.

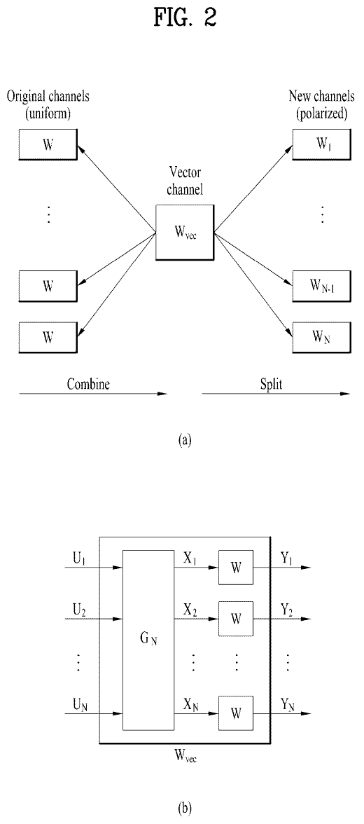

FIG. 2 illustrates the concept of channel combining and channel splitting for channel polarization. As illustrated in FIG. 2, when N copies of an original channel W are properly combined to create a vector channel W_{vec} and then are split into new polarized channels, the new polarized channels are categorized into channels having capacity C(W)=1 and channels having C(W)=0 if N is sufficiently large. In this case, since bits passing through the channels having the channel capacity C(W))=1 are transmitted without error, it is better to transmit information bits therethrough and, since bits passing through the channels having capacity C(W)=0 cannot transport information, it is better to transport frozen bits, which are meaningless bits, therethrough.

Referring to FIG. 2, copies of a given B-DMC W are combined in a recursive manner to output a vector channel W_{vec} given by X_{N}→Y_{N}, where N=2ⁿ and n is an integer equal to or greater than 0. Recursion always begins at the 0th level and W₁=W. If n is 1 (n=1), this means the first level of recursion in which two independent copies of W₁ are combined. If the above two copies are combined, a channel W₂: X₂→Y₂ is obtained. A transitional probability of this new channel W₂ may be represented by the following equation.

$${W}_{2} ( {y}_{1} , {y}_{2} \vert {u}_{1} , {u}_{2} ) = W ( {y}_{1} \vert {u}_{1} ⊕ {u}_{2} ) W ( {y}_{1} \vert {u}_{2} ) \qquad Equation 3$$

If the channel W₂ is obtained, two copies of the channel W₂ are combined to obtain a single copy of a channel W₄. Such recursion may be represented by W₄: X₄→Y₄ having the following transitional probability.

$${W}_{4} ( {y}_{1}^{4} \vert {u}_{1}^{4} ) = {W}_{2} ( {y}_{1}^{2} \vert {u}_{1} ⊕ {u}_{2} , {u}_{3} ⊕ {u}_{4} ) {W}_{2} ( {y}_{3}^{4} \vert {u}_{2} , {u}_{4} ) \qquad Equation 4$$

In FIG. 2, G_{N} is a size-N generator matrix. G₂ corresponds to the base matrix F illustrated in FIG. 1(b). G₄ may be represented by the following matrix.

$${G}_{4} = {[ \begin{matrix}1 & 0 & 0 & 0 \\ 0 & 0 & 1 & 0 \\ 0 & 1 & 0 & 0 \\ 0 & 0 & 0 & 1\end{matrix} ] [ \begin{matrix}1 & 0 \\ 1 & 1\end{matrix} ]}^{⊗ 2} = [ \begin{matrix}1 & 0 & 0 & 0 \\ 1 & 0 & 1 & 0 \\ 1 & 1 & 0 & 0 \\ 1 & 1 & 1 & 1\end{matrix} ] \qquad Equation 5$$

Herein, ⊗ denotes the Kronecker product, A^{⊗}^{ₙ}=A⊗A^{⊗}^{₍ₙ₋₁₎} for all n≥1, and A^{⊗}^{₀}=1.

The relationship between input u^{N}₁ to G_{N} and output x^{N}₁ of G_{N} of FIG. 2(b) may be represented as x^{N}₁=u^{N}₁G_{N}, where x^{N}₁={x₁, . . . , x_{N}}, u^{N}₁={u₁, . . . , u_{N}}

When N B-DMCs are combined, each B-DMC may be expressed in a recursive manner. That is, G_{N} may be indicated by the following equation.

$${G}_{N} = {B}_{N} {F}^{Wn} \qquad Equation 6$$

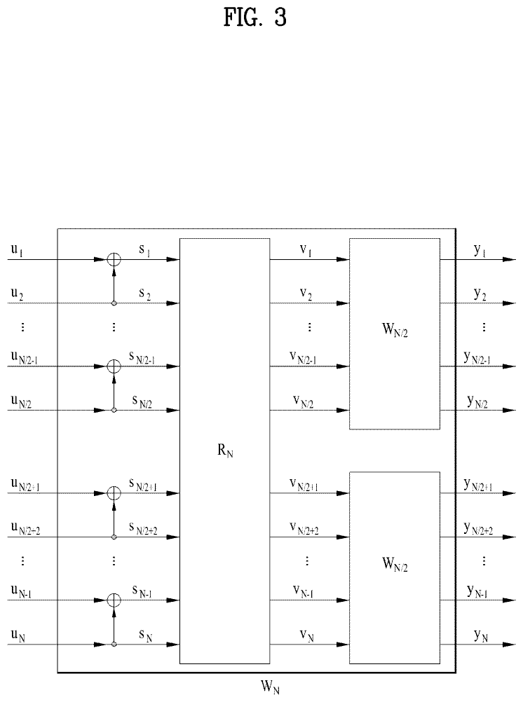

Herein, N=2ⁿ, n≥1, F^{⊗}^{ₙ}=F⊗F^{⊗}^{₍ₙ₋₁₎}, and F^{⊗}^{₀}=1. B_{N} is a permutation matrix known as a bit-reversal operation and B_{N}=R_{N}(I₂⊗B_{N/2}) and may be recursively computed. I₂ is a 2-dimensional identity matrix and this recursion is initialized to B₂=I₂. R_{N} is a bit-reversal interleaver and is used to map an input s^{N}₁={s₁, . . . , s_{N}} to an output x^{N}₁={s₁, s₃, . . . , s_{N-1}, s₂, . . . , s_{N}}. The bit-reversal interleaver may not be included in a transmitting side. The relationship of Equation is illustrated in FIG. 3.

FIG. 3 illustrates N-th level channel combining for a polar code.

A process of defining an equivalent channel for specific input after combining N B-DMCs Ws is called channel splitting. Channel splitting may be represented as a channel transition probability indicated by the following equation.

$${W}_{N}^{i} ( {y}_{1}^{N} , {u}_{1}^{i - 1} \vert {u}_{i} ) = {\sum }_{{u}_{i + 1}^{N}} \frac{1}{{2}^{N - 1}} {W}_{N} ( {y}_{1}^{N} \vert {u}_{1}^{N} ) \qquad Equation 7$$

Channel polarization has the following characteristics:
Conservation: C(W⁻)+C(W⁺)=2C(W),
Extremization: C(W⁻)≤C(W)≤C(W⁺).

When channel combining and channel splitting are performed, the following theorem may be obtained.

* Theorem: For any B-DMC W, channels {W_{N}⁽ⁱ⁾} are polarized in the following sense. For any fixed δ∈{0,1}, as N goes to infinity through powers of 2, the fraction of indexes i∈{1, . . . , N} for channel capacity I(W_{N}⁽ⁱ⁾)∈(1−δ,1] goes to I(W) and the faction of i for channel capacity I(W_{N}⁽ⁱ⁾)∈[0, δ) goes to 1−I(W). Hence, if N→∞, then channels are perfectly noisy or are polarized free of noise. These channels can be accurately recognized by the transmitting side. Therefore, bad channels are fixed and non-fixed bits may be transmitted on good channels.

That is, if the size N of polar codes is infinite, a channel has much noise or is free of noise, with respect to a specific input bit. This has the same meaning that the capacity of an equivalent channel for a specific input bit is divided into 0 or I(W).

Inputs of a polar encoder are divided into bit channels to which information data is mapped and bit channels to which the information data is not mapped. As described earlier, according to the theorem of the polar code, if a codeword of the polar code goes to infinity, the input bit channels may be classified into noiseless channels and noise channels. Therefore, if information is allocated to the noiseless bit channels, channel capacity may be obtained. However, in actuality, a codeword of an infinite length cannot be configured, reliabilities of the input bit channels are calculated and data bits are allocated to the input bit channels in order of reliabilities. In the present disclosure, bit channels to which data bits are allocated are referred to as good bit channels. The good bit channels may be input bit channels to which the data bits are mapped. Bit channels to which data is not mapped are referred to as frozen bit channels. A known value (e.g., 0) is input to the frozen bit channels and then encoding is performed. Any values which are known to the transmitting side and the receiving side may be mapped to the frozen bit channels. When puncturing or repetition is performed, information about the good bit channels may be used. For example, positions of codeword bits (i.e., output bits) corresponding to positions of input bits to which information bits are not allocated may be punctured.

FIG. 4 illustrates the concept of selecting position(s) to which information bit(s) are to be allocated in polar codes.

In FIG. 4, it is assumed that the size N of mother codes is 8, i.e., the size N of polar codes is 8, and a code rate is ½.

In FIG. 4, C(W) denotes the capacity of a channel W; and corresponds to the reliability of channels that input bits of a polar code experience. When channel capacities corresponding to input bit positions of the polar code are as illustrated in FIG. 8, reliabilities of the input bit positions are ranked as illustrated in FIG. 4 To transmit data at a code rate of ½, a transmitting device allocates 4 bits constituting the data to 4 input bit positions having high channel capacities among 8 input bit positions (i.e., input bit positions denoted as U₄, U₆, U₇, and U₄ among input bit positions U₁ to U₈ of FIG. 4) and freezes the other input bit positions. A generator matrix G₈ corresponding to the polar code of FIG. 4 is as follows. The generator matrix G₈ may be acquired based on Equation 6.

$${G}_{8} = [ \begin{matrix}1 & 0 & 0 & 0 & 0 & 0 & 0 & 0 \\ 1 & 1 & 0 & 0 & 0 & 0 & 0 & 0 \\ 1 & 0 & 1 & 0 & 0 & 0 & 0 & 0 \\ 1 & 1 & 1 & 1 & 0 & 0 & 0 & 0 \\ 1 & 0 & 0 & 0 & 1 & 0 & 0 & 0 \\ 1 & 1 & 0 & 0 & 1 & 1 & 0 & 0 \\ 1 & 0 & 1 & 0 & 1 & 0 & 1 & 0 \\ 1 & 1 & 1 & 1 & 1 & 1 & 1 & 1\end{matrix} ] \qquad Equation 8$$

The input bit positions denoted as U₁ to U₈ of FIG. 4 correspond one by one to rows from the lowest row to the highest row of G₈. Referring to FIG. 4, it may be appreciated that the input bit corresponding to U₈ affects all output coded bits. On the other hand, it may be appreciated that the input bit corresponding to U₁ affects only Y₁ among the output coded bits. Referring to Equation 12, when binary-input source bits U₁ to U₈ are multiplied by G₈, a row in which the input bits appear at all output bits is the lowest row [1, 1, 1, 1, 1, 1, 1, 1] in which all elements are 1, among rows of G₈. Meanwhile, a row in which the binary-input source bits appears at only one output bit is a row in which one element is 1 among the rows of G₈, i.e., a row [1, 0, 0, 0, 0, 0, 0, 0] in which a row weight is 1. Similarly, it may be appreciated that a row in which a row weight is 2 reflects input bits corresponding to the row in two output bits. Referring to FIG. 8 and Equation 12, U₁ to U₈ correspond one by one to the rows of G₈ and bit indexes for distinguishing between input positions of U₁ to U₈, i.e., bit indexes for distinguishing between the input positions, may be assigned to the rows of G₈.

Hereinafter, for Polar codes, it may be assumed that bit indexes from 0 to N−1 are sequentially allocated to rows of G_{N} starting from the highest row having the smallest row weight with respect to N input bits. For example, referring to FIG. 8, a bit index 0 is allocated to the input position of U₁, i.e., the first row of G₈ and a bit index 7 is allocated to the input position of U₈, i.e., the last row of G₈. However, since the bit indexes are used to indicate input positions of the polar code, a scheme different from the above allocation scheme may be used. For example, bit indexes from 0 to N−1 may be allocated staring from the lowest row having the largest row weight.

In the case of output bit indexes, as illustrated in FIG. 4 and Equation 8, it may be assumed that bit indexes from 0 to N−1 or bit indexes from 1 to N are assigned to columns from the first column having the largest column weight to the last column having the smallest column weight among columns of G_{N}.

In Polar codes, setting of information bits and frozen bits is one of the most important elements in the configuration and performance of the polar code. That is, determination of ranks of input bit positions may be an important element in the performance and configuration of the polar code. For Polar codes, bit indexes may distinguish input or output positions of the polar code. In the present disclosure, a sequence obtained by enumerating reliabilities of bit positions in ascending or descending order are referred to as a bit index sequence. That is, the bit index sequence represents reliabilities of input or output bit positions of the polar code in ascending or descending order. A transmitting device inputs information bits to input bits having high reliabilities based on the input bit index sequence and performs encoding using the polar code. A receiving device may discern input positions to which information bits are allocated or input positions to which frozen bits are allocated, using the same or corresponding input bit index sequence. That is, the receiving device may perform polar decoding using an input bit index sequence which is identical to or corresponds to an input bit sequence used by the transmitting device and using a corresponding polar code. In the following description, it may be assumed that an input bit sequence is predetermined so that information bit(s) may be allocated to input bit position(s) having high reliabilities.

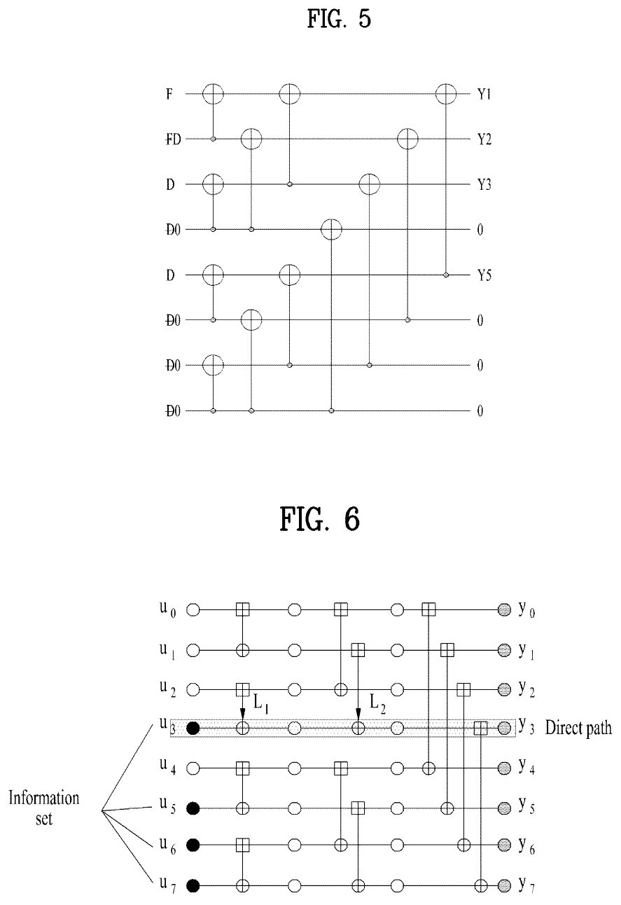

FIG. 5 illustrates puncturing and information bit allocation for a polar code. In FIG. 5, F denotes a frozen bit, D denotes an information bit, and 0 denotes a skipping bit.

Among coded bits, an information bit may be changed to a frozen bit according to the index or position of a punctured bit. For example, when output coded bits of a mother code with N=8 should be punctured in the order of Y8, Y7, Y6, Y4, Y5, Y3, Y2, and Y1 and a target code rate is ½, then Y8, Y7, Y6, and Y4 are punctured, U8, U7, U6, and U4 connected only to Y8, Y7, Y6, and Y4 are frozen to 0, and these input bits are not transmitted, as illustrated in FIG. 5. An input bit changed to a frozen bit by puncturing of a coded bit is referred to as a skipping bit or a shortening bit, and a corresponding input position is referred to as a skipping position or a shortening position. Shortening is a rate matching method of inserting a known bit into an input bit position connected to the position of an output bit desired to be transmitted while maintaining the size of input information (i.e., the size of an information block). Shortening is possible starting from an input corresponding to a column with a column weight of 1 in a generator matrix G_{N}, and next shortening may be performed on an input corresponding to a column with the column weight of 1 in the remaining matrix after a column and row with the column weight of 1 are removed. To prevent all information bits from being punctured, an information bit that should have been allocated to an information bit position may be reallocated in order of a high reliability within a set of frozen bit positions.

For the polar code, decoding is generally performed in the following order.
1. Low-reliability bit(s) are restored first. Although reliability varies depending on the structure of a decoder, an input bit index in an encoder (hereinafter, an encoder input bit index or bit index) having a low value usually has a low reliability, and thus decoding is generally performed sequentially, staring from a lower encoder input bit index.
2. When there is known bit information for a restored bit, the known bit is used together with the restored bit or process 1 is omitted and a known bit for a specific input bit position is immediately used to restore an information bit, which is an unknown bit. The information bit may be a source information bit (e.g., a bit of a transport block) or a CRC bit.

### Embodiment

Puncturing techniques for polar codes are widely used in the design process of polar codes of various lengths. Traditional polar code puncturing techniques are divided into a puncturing technique for rate-matching and a puncturing technique for rate compatibility. A puncturing-based rate-compatible code is designed to adjust the number of punctured bits and adaptively use the same encoding/decoding structure according to various channel environments by using a nested code structure through puncturing. Although existing puncturing-based rate-compatible design techniques for polar codes include techniques using the reliability of a bit channel and a distance to an information set, they do not reflect the structural characteristics of a polar code and the decoding reliability of an actual information set. Therefore, to increase the error correction performance of a rate-compatible code, there is a need for designing a puncturing method that reflects the structure of a polar code.

Hereinbelow, the disclosure proposes a technology of designing a rate-compatible polar code using a puncturing technique that reflects the structure of the polar code. Specifically, the disclosure defines a restoration score for an information bit of the polar code. The restoration score may be obtained by analyzing a message received in a direct path, which is a core decoding path within a butterfly network of the polar code, for an individual information bit. In addition, the disclosure proposes an algorithm of estimating the performance of a punctured code by extending a restoration score to a message delivered after puncturing, and detecting an optimal puncturing pattern accordingly. A rate-compatible polar code with high-performance error correction capability may be designed using the algorithm. The high-performance rate-compatible polar code may improve the effectiveness of communication retransmission implementation.

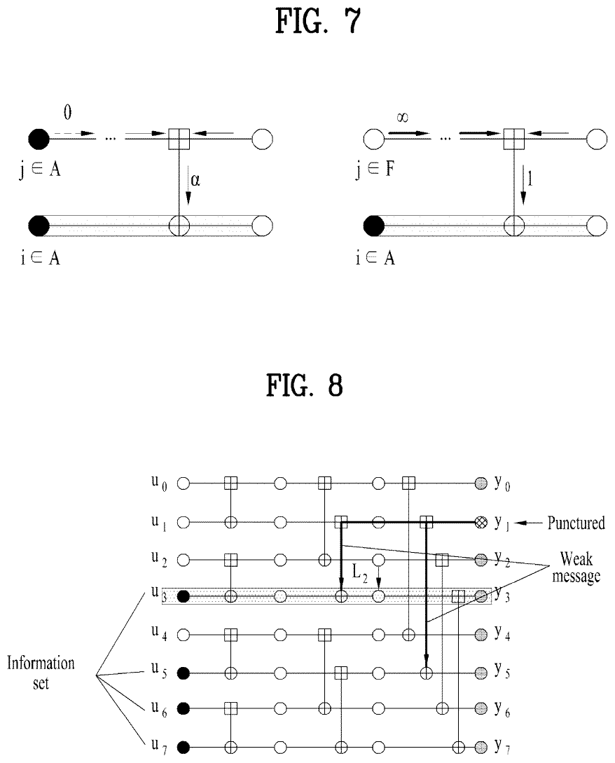

First, to describe the disclosure, the restoration score of an information bit for selection of a punctured bit is defined. FIGS. 6 to 8 are exemplary diagrams describing restoration scores. Referring to FIG. 6, a direct path i, which is a path horizontally connecting a message bit u; and a codeword bit yᵢ within a butterfly network of a polar code, plays a key role during decoding of the individual message bit uᵢ. A ⊕ operation within the direct path delivers a log-likelihood ratio message from another direct path. The initial reliability of the individual message bit u; may be estimated through the number of ⊕ operations in the direct path. Referring to FIG. 7, when a direct path for transmitting a message is a path connected to a frozen bit F, a fixed bit value at a message end propagates a ∞ message, thereby delivering higher-reliability information. Therefore, when the number of ⊕ operations is counted, a weight counter c_{i,j} may be set by Equation 9 according to the characteristics of a direct path j that delivers a message to the direct path i.

$${c}_{i , j} = \{ \begin{matrix}α if j ∈ 𝒜 , & \\ & where 0 < α < 1 \\ 1 if j ∈ ℱ , & \end{matrix} \qquad [ Equation 9 ]$$

Herein, A represents an information bit set, and F represents a frozen bit set.

A set of paths connected by a ⊕ operation within a direct path may be calculated by changing the position of 1 to 0 in the binary expression of a corresponding message bit.

$$[ Equation 10 ]$$

$$𝒩 ( i ) = \{ j : j = {( {i}_{1} , {i}_{2} , … , {i}_{k} ⊕ 1 , … , {i}_{n} )}_{2} , \\ ∀ k ∈ \{ k : {i}_{k} = 1 \} where i = {( {i}_{1} {i}_{2} , … , {i}_{n} )}_{2} \}$$

Based on a defined weight counter, an initial restoration score sᵢ of the information bit uᵢ may be defined as Equation 11.

$${s}_{i} = {\sum }_{j ∈ 𝒩 ( i )} {c}_{i , j} \qquad [ Equation 11 ]$$

Referring to FIG. 8, when a codeword bit i (i.e., yᵢ) of the polar code is punctured, the bit is not transmitted through a channel, and a log-likelihood ratio value of 0 is input during the decoding process. This weakens the message transmitted from the direct path i to another direct path, thereby lowering the reliability of an information bit of another direct path (e.g., direct path 3 or direct path 5) connected to the direct path i. Therefore, when the codeword bit (e.g., the codeword bit y₁) is punctured according to a puncturing pattern [symbol] , the puncturing restoration score sᵢ′( [symbol] ) of the information bit i may be calculated (e.g., s′₃(P)) by removing the weight counter transmitted in the puncturing direct path (e.g., direct path 1) from the corresponding initial restoration score.

$${s}_{i}^{′} ( 𝒫 ) = {s}_{i} - {\sum }_{j ∈ 𝒫} {c}_{i , j} \qquad [ Equation 12 ]$$

The puncturing restoration score indicates the reliability of the individual information bit reflecting the puncture pattern [symbol] . The performance of the code after puncturing is determined by a lowest-reliability bit among the information bits. Therefore, when the puncturing pattern is applied, the minimum of the puncturing restoration scores of the individual information bits may be represented as the performance of the code for the puncturing pattern. In other words, a smaller minimum value of the puncturing restoration scores for the puncturing pattern means that the performance of the code for the puncture pattern is lower. For example, when a plurality of puncturing patterns are assumed, a puncturing pattern with a largest minimum value of puncturing restoration scores may maximize the performance of the code. When a plurality of puncturing patterns have the same minimum value, next smallest puncturing restoration scores may be compared. In this manner, a puncturing pattern that may maximize the reliability of individual information bits may be selected. In addition, a single puncturing bit may be selected, which maximizes the reliability of individual information bits by forming a plurality of puncturing patterns by adding a single puncturing bit at different positions in an existing puncturing pattern, and then comparing the puncturing restoration scores of the plurality of puncturing patterns.

The proposed method may generate a puncturing pattern [symbol] through the following process by using an information set A and a target number of puncturing bits, π as an input.

### 1. Initialization

The puncturing pattern, the initial restoration score, and the number of punctured bits are set to initial values by [symbol] ⁽⁰⁾=∅, sᵢ= [symbol] , ∀i∈ [symbol] , and [symbol] =0, respectively, and m=0.

### 2. Select Puncturing Candidate Bits

Bits that have not been punctured so far in a frozen bit set are selected as puncturing candidate bits.

$${ℬ}^{( ℓ )} = ℱ \backslash {𝒫}^{( ℓ )} \qquad [ Equation 13 ]$$

### 3. Calculate Minimum Restoration Score

For each single puncturing candidate bit p selected from a puncturing candidate bit set [symbol] , the puncturing restoration score of the bit is calculated when the bit is punctured. Specifically, each single puncturing candidate bit p is added to the current puncturing pattern [symbol] (e.g., [symbol] ) to configure a temporary puncturing pattern (e.g., [symbol] ∪p), and then the puncturing restoration score is calculated for the temporary puncturing pattern.

$${s}_{i}^{′} ( {𝒫}^{( ℓ )} ⋃ p ) = {s}_{i} - {\sum }_{j ∈ 𝒫} {c}_{i , j} , ∀ i ∈ 𝒜 \qquad [ Equation 14 ]$$

An m^{th} minimum puncturing restoration score σₚ is calculated for the temporary puncturing pattern.

$${σ}_{p} = μ ( {𝒫}^{( ℓ )} ⋃ p , m ) , \qquad [ Equation 15 ]$$

Herein, μ( [symbol] , m) is a function that outputs the m^{th} minimum puncturing restoration score for the puncturing pattern [symbol] .

### 4. Update Puncturing Candidate Bits

The puncturing candidate bits are updated with a set of puncturing bits with the maximum of a plurality of minimum puncturing restoration scores.

$${ℬ}^{( ℓ )} = \{ p : {σ}_{p} = {max}_{{p}^{′}} {σ}_{{p}^{′}} \}$$

### 5. Select Puncturing Bit

If |B^{(l)}|=1, the candidate bit is added to the puncturing bit set.

$${𝒫}^{( ℓ + 1 )} ← {𝒫}^{( ℓ )} ⋃ {B}^{( ℓ )}$$

Otherwise, m←m+1 and the procedure goes to process 3. That is, when there are a plurality of puncturing candidate bits with the same maximum value among m^{th} minimum puncturing restoration scores, a single puncturing bit may be selected, which maximizes the reliability of an individual information bit by comparing (m+1)^{th} minimum puncturing restoration scores.

### 6. Check Target Code Rate

If | [symbol] |=π, a puncturing a pattern [symbol] is output.

Otherwise, [symbol] ← [symbol] +1 and the procedure goes to process 2 to select an additional puncturing bit.

Table 5 illustrates an exemplary puncturing pattern for a (512,256) polar code designed according to the proposed method. The proposed puncturing pattern is obtained in a nested form between code rates.

TABLE 4

| Code | Number of | |
|---|---|---|
| rate | punctured | |
| (R) | bits | Puncturing pattern |
| 0.65 | 122 | 1, 2, 3, 4, 5, 6, 7, 8, 9, 10, 11, 12, 13, 14, 15, 16, 17, 18, 19, 20, 21, 22, 23, 24, |
| | | 25, 26, 27, 29, 33, 34, 35, 36, 37, 38, 39, 41, 42, 43, 45, 49, 50, 51, 53, 65, 66, 67, 68, |
| | | 69, 70, 71, 73, 74, 75, 77, 81, 82, 97, 129, 130, 131, 132, 133, 134, 137, 145, 161, |
| | | 257, 258, 259, 260, 261, 262, 265, 273, 289, 32, 28, 30, 31, 40, 44, 46, 52, 72, 47, |
| | | 54, 55, 76, 78, 79, 48, 88, 136, 58, 84, 86, 90, 59, 61, 144, 104, 180, 122, 87, 100, |
| | | 102, 103, 106, 114, 200, 57, 83, 85, 89, 98, 99, 101, 135, 138, 139, 141, 146 |
| 0.73 | 164 | 1, 2, 3, 4, 5, 6, 7, 8, 9, 10, 11, 12, 13, 14, 15, 16, 17, 18, 19, 20, 21, 22, 23, 24, |
| | | 25, 26, 27, 29, 33, 34, 35, 36, 37, 38, 39, 41, 42, 43, 45, 49, 50, 51, 53, 65, 66, 67, 68, |
| | | 69, 70, 71, 73, 74, 75, 77, 81, 82, 97, 129, 130, 131, 132, 133, 134, 137, 145, 161, |
| | | 257, 258, 259, 260, 261, 262, 265, 273, 289, 32, 28, 30, 31, 40, 44, 46, 52, 72, 47, |
| | | 54, 55, 76, 78, 79, 48, 88, 136, 58, 84, 86, 90, 59, 61, 144, 104, 180, 122, 87, 100, |
| | | 102, 103, 106, 114, 200, 57, 83, 85, 89, 98, 99, 101, 135, 138, 139, 141, 146, 147, |
| | | 149, 153, 162, 163, 165, 63, 158, 92, 110, 140, 142, 148, 164, 91, 93, 119, 105, 113, |
| | | 150, 143, 151, 154, 155, 157, 280, 229, 194, 195, 197, 172, 264, 299, 309, 333, |
| | | 276, 272, 193, 263, 266, 267, 269 |
| 0.83 | 205 | 1, 2, 3, 4, 5, 6, 7, 8, 9, 10, 11, 12, 13, 14, 15, 16, 17, 18, 19, 20, 21, 22, 23, 24, |
| | | 25, 26, 27, 29, 33, 34, 35, 36, 37, 38, 39, 41, 42, 43, 45, 49, 50, 51, 53, 65, 66, 67, 68, |
| | | 69, 70, 71, 73, 74, 75, 77, 81, 82, 97, 129, 130, 131, 132, 133, 134, 137, 145, 161, |
| | | 257, 258, 259, 260, 261, 262, 265, 273, 289, 32, 28, 30, 31, 40, 44, 46, 52, 72, 47, |
| | | 54, 55, 76, 78, 79, 48, 88, 136, 58, 84, 86, 90, 59, 61, 144, 104, 180, 122, 87, 100, |
| | | 102, 103, 106, 114, 200, 57, 83, 85, 89, 98, 99, 101, 135, 138, 139, 141, 146, 147, |
| | | 149, 153, 162, 163, 165, 63, 158, 92, 110, 140, 142, 148, 164, 91, 93, 119, 105, 113, |
| | | 150, 143, 151, 154, 155, 157, 280, 229, 194, 195, 197, 172, 264, 299, 309, 333, |
| | | 276, 272, 193, 263, 266, 267, 269, 274, 115, 169, 177, 159, 118, 170, 108, 270, |
| | | 95, 109, 331, 279, 275, 277, 290, 291, 293, 166, 329, 179, 278, 298, 305, 196, 199, |
| | | 217, 174, 60, 173, 324, 283, 390, 321, 209, 152, 117, 198, 295, 201, 322 |

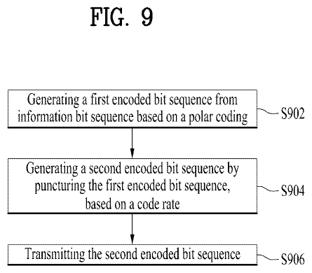

FIG. 9 illustrates a signal transmission process according to an embodiment of the disclosure. Referring to FIG. 9, a transmission device may generate a first encoded information bit sequence from an information bit sequence based on a polar code (S902). Then, the transmission device may generate a second encoded bit sequence by puncturing the first encoded bit sequence based on a code rate (S904) and transmit the generated second encoded bit sequence (S906). The first encoded bit sequence may be obtained based on a puncturing pattern (e.g., Table 4) designed according to the proposed method of the disclosure, and the puncturing pattern may satisfy a nested property.

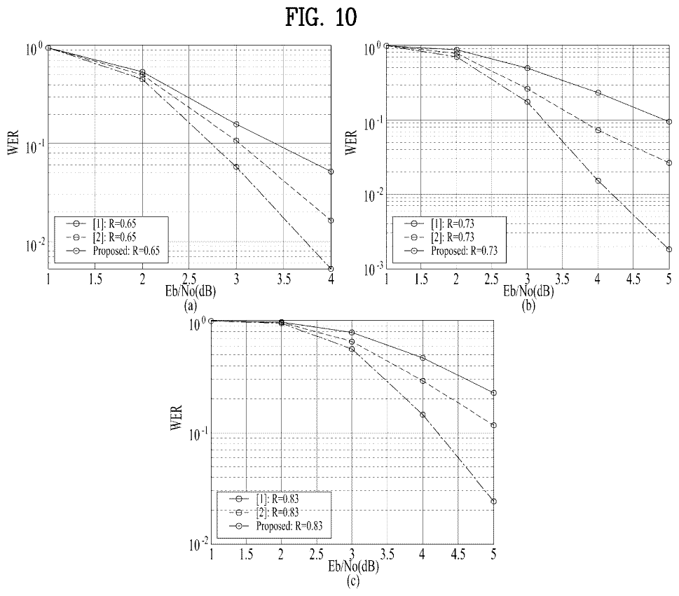

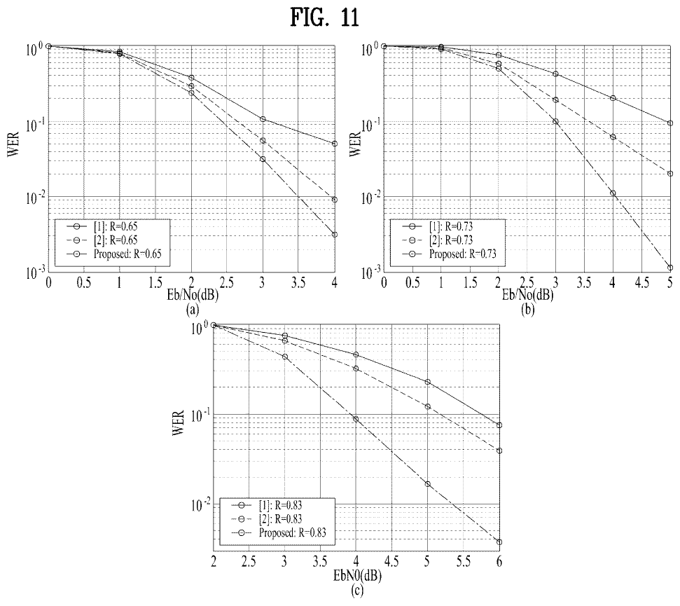

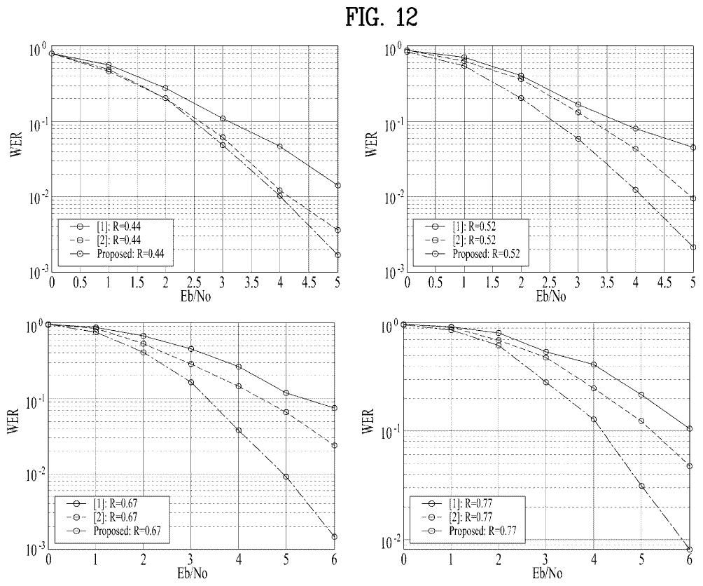

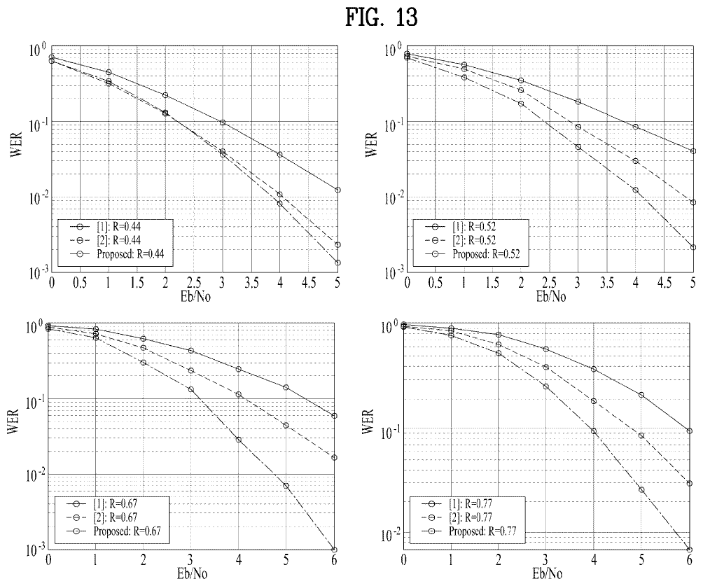

FIGS. 10 and 11 illustrate the performance comparison simulation results of proposed rate-compatible codes of a (512,256) polar code. The puncturing pattern of Table 4 was used in the simulation. FIG. 10 illustrates simulation results of cases of a belief propagation (BP) decoder, a maximum repetition number L=10, and additive white Gaussian noise (AWGN) channel: (a) R (code rate)=0.65, (b) R=0.73, and (c) R=0.83. FIG. 11 illustrates simulation results of cases of a successful cancellation (SC)-List decoder, L=8, and AWGN channel: (a) R=0.65, (b) R=0.73, and (c) R=0.83. FIGS. 12 and 13 illustrate the performance comparison simulation results of proposed rate-compatible codes of a (512, 64) polar code. FIG. 12 illustrates simulation results of cases of a BP decoder, a maximum repletion number L=10, and AWGN channel: (a) R=0.44, (b) R=0.52, (c) R=0.67, and (d) R=0.77. FIG. 13 illustrates simulation results of cases of an SC-List decoder, L=8, and AWGN channel: (a) R=0.65, (b) R=0.73, and (c) R=0.83. Referring to the drawings, when a puncturing pattern is designed according to the proposed design method of the disclosure, error correction performance is improved for various decoding algorithms, compared to an existing puncturing pattern design algorithm.

The polar code according to the disclosure may be used in various communication environments. For example, the rate-compatible polar code according to the disclosure may be applied to wireless communication (e.g., 5G and 6G communication) to improve the effectiveness of communication retransmission implementation. An exemplary system to which the disclosure is applicable will be described below.

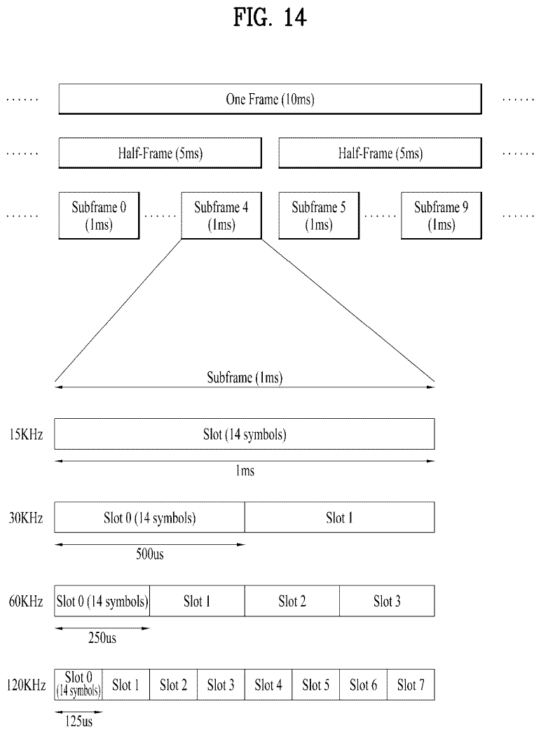

FIG. 14 illustrates an example of a frame structure used in a 3GPP-based wireless communication system. The frame structure of FIG. 14 is purely exemplary and the number of subframes, the number of slots, and the number of symbols, in a frame, may be variously changed. In an NR system, different OFDM numerologies (e.g., subcarrier spacings (SCSs)) may be configured for multiple cells which are aggregated for one UE. Accordingly, the (absolute time) duration of a time resource including the same number of symbols (e.g., a subframe, a slot, or a transmission time interval (TTI)) may be differently configured for the aggregated cells. Here, the symbol may include an OFDM symbol (or cyclic prefix-OFDM (CP-OFDM) symbol) and an SC-FDMA symbol (or discrete Fourier transform-spread-OFDM (DFT-s-OFDM) symbol). In the present disclosure, the symbol, the OFDM-based symbol, the OFDM symbol, the CP-OFDM symbol, and the DFT-s-OFDM symbol are used interchangeably.

Referring to FIG. 14, in the NR system, UL and DL transmissions are organized into frames. Each frame has a duration of T_{f}=10 ms and is divided into two half-frames of 5 ms each. Each half-frame includes 5 subframes and a duration T_{sf} of a single subframe is 1 ms. Subframes are further divided into slots and the number of slots in a subframe depends on a subcarrier spacing. Each slot includes 14 or 12 OFDM symbols based on a cyclic prefix. In a normal CP, each slot includes 14 OFDM symbols and, in an extended CP, each slot includes 12 OFDM symbols. The numerology depends on an exponentially scalable subcarrier spacing Δf=2^{u}*15 kHz. The table below shows the number of OFDM symbols (N^{slot}_{symb}) per slot, the number of slots (N^{frame,u}ₛₗₒₜ) per frame, and the number of slots (N^{subframe,u}ₛₗₒₜ) per subframe.

TABLE 5

| u | N^{slot}_{symb} | N^{frame, u}ₛₗₒₜ | N^{subframe, u}ₛₗₒₜ |
|---|---|---|---|
| 0 | 14 | 10 | 1 |
| 1 | 14 | 20 | 2 |
| 2 | 14 | 40 | 4 |
| 3 | 14 | 80 | 8 |
| 4 | 14 | 160 | 16 |

The table below shows the number of OFDM symbols per slot, the number of slots per frame, and the number of slots per subframe, according to the subcarrier spacing Δf=2^{u}*15 kHz.

TABLE 6

| u | N^{slot}_{symb} | N^{frame, u}ₛₗₒₜ | N^{subframe, u}ₛₗₒₜ |
|---|---|---|---|
| 2 | 12 | 40 | 4 |

A slot includes a plurality of (e.g., 14 or 12) symbols in the time domain. For each numerology (e.g., SCS) and carrier, a resource grid of N^{size,u}_{grid,x}*N^{RB}_{sc} subcarriers and N^{subframe,u}_{symb} OFDM symbols is defined, starting at a common resource block (CRB) N^{size,u}_{grid} indicated by higher layer signaling (e.g. RRC signaling), where N^{size,u}_{grid,x} is the number of resource blocks (RBs) in the resource grid and the subscript x is DL for downlink and UL for uplink. N^{RB}_{sc} is the number of subcarriers per RB. In the 3GPP based wireless communication system, N^{RB}_{sc} is typically 12. One resource grid may be present for a given antenna port p, an SCS configuration u, and a transmission direction (DL or UL). The carrier bandwidth N^{size,u}_{grid} for the SCS configuration u is provided by a higher layer parameter (e.g., RRC parameter). Each element in the resource grid for the antenna port p and SCS configuration u is referred to as a resource element (RE), and one complex symbol may be mapped to each RE. Each RE in the resource grid is uniquely identified by an index k in the frequency domain and an index 1 representing a symbol location relative to a reference point in the time domain. In the NR system, an RB is defined by 12 consecutive subcarriers in the frequency domain. In the NR system, RBs may be classified into CRBs and physical resource blocks (PRBs). CRBs are numbered from 0 upwards in the frequency domain for the SCS configuration u. The center of subcarrier 0 of CRB 0 for the SCS configuration u coincides with ‘point A’ which serves as a common reference point for RB grids. PRBs are defined within a bandwidth part (BWP) and numbered from 0 to N^{size}_{BWP,i}−1, where i is the number of the bandwidth part. The relationship between a CRB n_{CRB} and a PRB n_{PRB} in a bandwidth part i is defined as follows: n_{PRB}=n_{CRB}+N^{size}_{BWP,i}, where N^{size}_{BWP,i} is a CRB where the bandwidth part starts relative to CRB 0. The BWP includes a plurality of consecutive RBs. A carrier may include a maximum of N (e.g., 5) BWPs.

In the NR system, polar codes are used for channel coding of data on a broadcast channel (BCH) transmitted/received over a physical broadcast channel (PBCH), DCI transmitted/received over a PDCCH, and UCI transmitted/received over a PUCCH or a PUSCH.

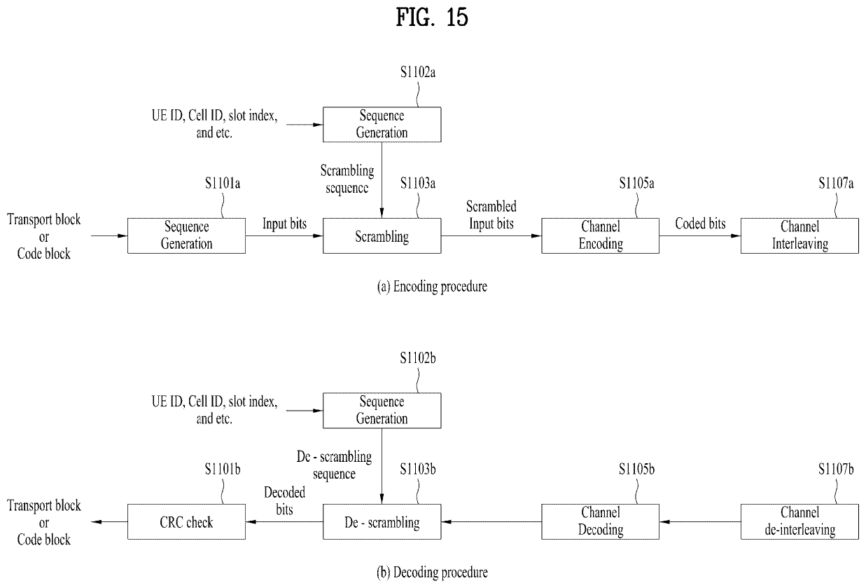

FIG. 15 illustrates encoding and decoding processes in the conventional LTE system. In particular, FIG. 15(a) illustrates an encoding process including scrambling, and FIG. 15(b) illustrates a decoding process including de-scrambling.

Referring to FIG. 15(a), a transmission device obtains input bits by adding a CRC code to a transport block or code block (S1101a) and then scrambles the input bits based on a scrambling sequence (S1103a). The transmission device generates coded bits by performing channel encoding on the scrambled input bits (S1105a) and then performs channel interleaving on the coded bits (S1107a). Referring to FIG. 15(b), a receiving device obtains coded bits by performing channel de-interleaving on received bits based on a channel interleaving pattern applied in the encoding process or a channel interleaving pattern related thereto (S1107b). The receiving device obtains scrambled bits by performing channel decoding on the coded bits (S1105b). The receiving device obtains a sequence of decoded bits (hereinafter referred to as a decoded bit sequence) by de-scrambling the scrambled bits based on a scrambling sequence (S1103b). The receiving device checks whether there is an error in the decoded bit sequence based on CRC bits in the decoded bit sequence (S1101b). If a CRC for the decoded bit sequence fails, the receiving device may determine that decoding of the received signal has failed. If the CRC for the decoded bit sequence is successful, the receiving device may determine that the decoding process is successful and then obtain a transport block or code block by removing the CRC code from the decoding bit sequence.

In FIG. 15(a), CRC generation (S1101a), sequence generation (S1102a), scrambling (S1103a), channel encoding (S1105a), and channel interleaving (S1107a) may be performed by a CRC code generator, sequence generator, scrambler, channel encoder, and channel interleaver, respectively. The CRC code generator, sequence generator, scrambler, channel encoder, and channel interleaver may be configured as part of a processor of the transmission device and operate under the control of the processor of the transmission device. In FIG. 13(b), CRC checking (S1101b), sequence generation (S1102b), de-scrambling (S1103b), channel decoding (S1105b), and channel interleaving (S1107b) may be performed by a CRC checker, sequence generator, de-scrambler, channel decoder, and channel interleaver, respectively. The CRC checker, sequence generator, de-scrambler, channel decoder, and channel interleaver may be configured as part of a processor of the receiving device and operate under the control of the processor of the receiving device. In the conventional LTE system, a scrambler generates an m-sequence based on a UE ID, cell ID, and/or slot index. Subsequently, the scrambler scrambles input bits input to the scrambler, which consist of information bits and CRC bits, based on the generated m-sequence. A de-scrambler generates an m-sequence based on a UE ID, cell ID, and/or slot index. Then, the de-scrambler de-scrambles input bits input the de-scrambler, which consist of information bits and CRC bits, based on the generated m-sequence.

Details of the encoding and decoding processes in the conventional LTE system may be found in 3GPP TS 36.211, 3GPP TS 36.212, 3GPP TS 36.331, and 3GPP TS 36.331. Similarly, details of the encoding and decoding processes in the NR system may be found in 3GPP TS 38.211, 3GPP TS 38.212, 3GPP TS 38.213, 3GPP TS 38.214, and 3GPP TS 38.331.

The methods proposed in the present disclosure may be used in various communication environments and is applicable to both wired and wireless communication technologies. The various details, functions, procedures, proposals, methods, and/or operational flowcharts described in this document may be applied to a variety of fields that require wireless communication/connections (e.g., 4G network (LTE network), 5G network (NR network), etc.) between devices.

Hereinafter, a description will be given in detail with reference to the drawings. In the following drawings/descriptions, the same reference numerals may denote the same or corresponding hardware blocks, software blocks, or functional blocks unless specified otherwise.

In the present disclosure, at least one memory (e.g., memory 104 or 204) may be configured store instructions or programs. The instructions or programs, when executed, may cause at least one processor operably connected to the at least one memory to perform operations according to embodiments or implementations of the present disclosure.

In the present disclosure, a computer-readable storage medium may be configured to store at least one instruction or computer program. The at least one instruction or computer program, when executed by at least one processor, may cause the at least one processor to perform operations according to embodiments or implementations of the present disclosure.

In the present disclosure, a computer program may include program code stored on at least one computer-readable (non-volatile) storage medium and, when executed, configured to perform operations according to some embodiments or implementations of the present disclosure. The computer program may be provided in the form of a computer program product. The computer program product may include at least one computer-readable (non volatile) storage medium. The computer-readable storage medium may include the program code that, when executed, (causes at least one processor) to perform operations according to some embodiments or implementations of the present specification.

In the present disclosure, a processing device or apparatus may include at least one processor and at least one computer memory connectable to the at least one processor. The at least one computer memory may be configured to store instructions or programs. The instructions or programs, when executed, may cause the at least one processor operably connected to the at least one memory to perform operations according to embodiments or implementations of the present disclosure.

In the present disclosure, a communication device may include: at least one processor; and at least one computer memory operably connected to the at least one processor and configured to store instructions that, when executed, cause the at least one processor to perform operations according to example(s) of the present disclosure, which will be described.

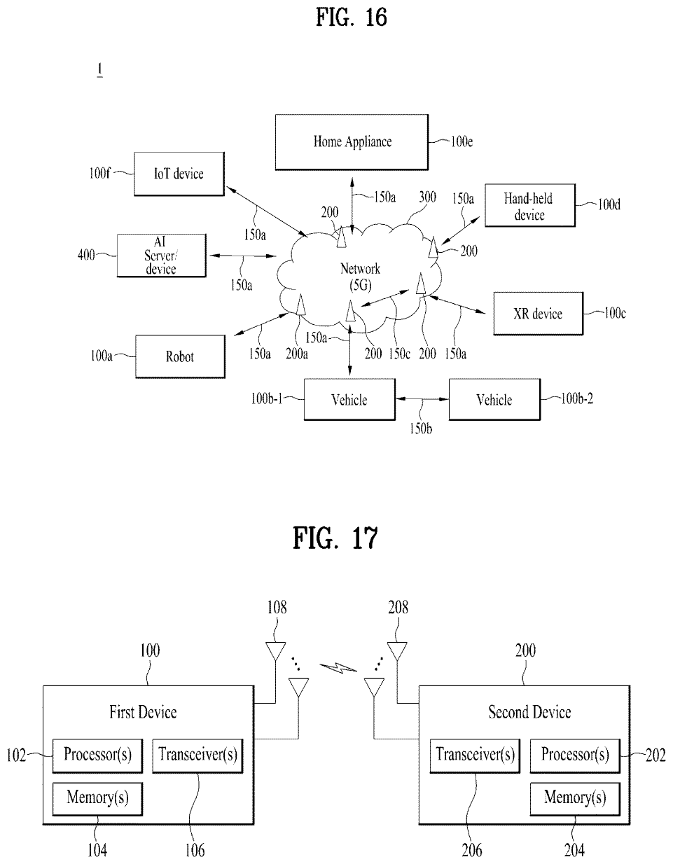

FIG. 16 illustrates a communication system applied to the present disclosure.

Referring to FIG. 16, a communication system 1 applied to the present disclosure includes wireless devices, Base Stations (BSs), and a network. Herein, the wireless devices represent devices performing communication using Radio Access Technology (RAT) (e.g., 5G New RAT (NR)) or Long-Term Evolution (LTE)) and may be referred to as communication/radio/5G devices. The wireless devices may include, without being limited to, a robot 100a, vehicles 100b-1 and 100b-2, an eXtended Reality (XR) device 100c, a hand-held device 100d, a home appliance 100e, an Internet of Things (IoT) device 100f, and an Artificial Intelligence (AI) device/server 400. For example, the vehicles may include a vehicle having a wireless communication function, an autonomous driving vehicle, and a vehicle capable of performing communication between vehicles. Herein, the vehicles may include an Unmanned Aerial Vehicle (UAV) (e.g., a drone). The XR device may include an Augmented Reality (AR)/Virtual Reality (VR)/Mixed Reality (MR) device and may be implemented in the form of a Head-Mounted Device (HMD), a Head-Up Display (HUD) mounted in a vehicle, a television, a smartphone, a computer, a wearable device, a home appliance device, a digital signage, a vehicle, a robot, etc. The hand-held device may include a smartphone, a smartpad, a wearable device (e.g., a smartwatch or a smartglasses), and a computer (e.g., a notebook). The home appliance may include a TV, a refrigerator, and a washing machine. The IoT device may include a sensor and a smartmeter. For example, the BSs and the network may be implemented as wireless devices and a specific wireless device 200a may operate as a BS/network node with respect to other wireless devices.

The wireless devices 100a to 100f may be connected to the network 300 via the BSs 200. An AI technology may be applied to the wireless devices 100a to 100f and the wireless devices 100a to 100f may be connected to the AI server 400 via the network 300. The network 300 may be configured using a 3G network, a 4G (e.g., LTE) network, or a 5G (e.g., NR) network. Although the wireless devices 100a to 100f may communicate with each other through the BSs 200/network 300, the wireless devices 100a to 100f may perform direct communication (e.g., sidelink communication) with each other without passing through the BSs/network. For example, the vehicles 100b-1 and 100b-2 may perform direct communication (e.g. Vehicle-to-Vehicle (V2V)/Vehicle-to-everything (V2X) communication). The IoT device (e.g., a sensor) may perform direct communication with other IoT devices (e.g., sensors) or other wireless devices 100a to 100f.

Wireless communication/connections 150a, 150b, or 150c may be established between the wireless devices 100a to 100f/BS 200, or BS 200/BS 200. Herein, the wireless communication/connections may be established through various RATs (e.g., 5G NR) such as uplink/downlink communication 150a, sidelink communication 150b (or, D2D communication), or inter BS communication (e.g. relay, Integrated Access Backhaul (IAB)). The wireless devices and the BSs/the wireless devices may transmit/receive radio signals to/from each other through the wireless communication/connections 150a and 150b. For example, the wireless communication/connections 150a and 150b may transmit/receive signals through various physical channels. To this end, at least a part of various configuration information configuring processes, various signal processing processes (e.g., channel encoding/decoding, modulation/demodulation, and resource mapping/demapping), and resource allocating processes, for transmitting/receiving radio signals, may be performed based on the various proposals of the present disclosure

FIG. 17 illustrates a wireless device applicable to the present disclosure.

Referring to FIG. 17, a first wireless device 100 and a second wireless device 200 may transmit radio signals through a variety of RATs (e.g., LTE and NR). Herein, {the first wireless device 100 and the second wireless device 200} may correspond to {the wireless device 100x and the BS 200} and/or {the wireless device 100x and the wireless device 100x} of FIG. 24.

The first wireless device 100 may include one or more processors 102 and one or more memories 104 and additionally further include one or more transceivers 106 and/or one or more antennas 108. The processor(s) 102 may control the memory(s) 104 and/or the transceiver(s) 106 and may be configured to implement the descriptions, functions, procedures, proposals, methods, and/or operational flowcharts disclosed in this document. For example, the processor(s) 102 may process information within the memory(s) 104 to generate first information/signals and then transmit radio signals including the first information/signals through the transceiver(s) 106. The processor(s) 102 may receive radio signals including second information/signals through the transceiver 106 and then store information acquired by processing the second information/signals in the memory(s) 104. The memory(s) 104 may be connected to the processor(s) 102 and may store a variety of information related to operations of the processor(s) 102. For example, the memory(s) 104 may store software code including commands for performing a part or the entirety of processes controlled by the processor(s) 102 or for performing the descriptions, functions, procedures, proposals, methods, and/or operational flowcharts disclosed in this document. Herein, the processor(s) 102 and the memory(s) 104 may be a part of a communication modem/circuit/chip designed to implement RAT (e.g., LTE or NR). The transceiver(s) 106 may be connected to the processor(s) 102 and transmit and/or receive radio signals through one or more antennas 108. Each of the transceiver(s) 106 may include a transmitter and/or a receiver. The transceiver(s) 106 may be interchangeably used with Radio Frequency (RF) unit(s). In the present disclosure, the wireless device may represent a communication modem/circuit/chip.

The second wireless device 200 may include one or more processors 202 and one or more memories 204 and additionally further include one or more transceivers 206 and/or one or more antennas 208. The processor(s) 202 may control the memory(s) 204 and/or the transceiver(s) 206 and may be configured to implement the descriptions, functions, procedures, proposals, methods, and/or operational flowcharts disclosed in this document. For example, the processor(s) 202 may process information within the memory(s) 204 to generate third information/signals and then transmit radio signals including the third information/signals through the transceiver(s) 206. The processor(s) 202 may receive radio signals including fourth information/signals through the transceiver(s) 106 and then store information acquired by processing the fourth information/signals in the memory(s) 204. The memory(s) 204 may be connected to the processor(s) 202 and may store a variety of information related to operations of the processor(s) 202. For example, the memory(s) 204 may store software code including commands for performing a part or the entirety of processes controlled by the processor(s) 202 or for performing the descriptions, functions, procedures, proposals, methods, and/or operational flowcharts disclosed in this document. Herein, the processor(s) 202 and the memory(s) 204 may be a part of a communication modem/circuit/chip designed to implement RAT (e.g., LTE or NR). The transceiver(s) 206 may be connected to the processor(s) 202 and transmit and/or receive radio signals through one or more antennas 208. Each of the transceiver(s) 206 may include a transmitter and/or a receiver. The transceiver(s) 206 may be interchangeably used with RF unit(s). In the present disclosure, the wireless device may represent a communication modem/circuit/chip.

Hereinafter, hardware elements of the wireless devices 100 and 200 will be described more specifically. One or more protocol layers may be implemented by, without being limited to, one or more processors 102 and 202. For example, the one or more processors 102 and 202 may implement one or more layers (e.g., functional layers such as PHY, MAC, RLC, PDCP, RRC, and SDAP). The one or more processors 102 and 202 may generate one or more Protocol Data Units (PDUs) and/or one or more Service Data Unit (SDUs) according to the descriptions, functions, procedures, proposals, methods, and/or operational flowcharts disclosed in this document. The one or more processors 102 and 202 may generate messages, control information, data, or information according to the descriptions, functions, procedures, proposals, methods, and/or operational flowcharts disclosed in this document. The one or more processors 102 and 202 may generate signals (e.g., baseband signals) including PDUs, SDUs, messages, control information, data, or information according to the descriptions, functions, procedures, proposals, methods, and/or operational flowcharts disclosed in this document and provide the generated signals to the one or more transceivers 106 and 206. The one or more processors 102 and 202 may receive the signals (e.g., baseband signals) from the one or more transceivers 106 and 206 and acquire the PDUs, SDUs, messages, control information, data, or information according to the descriptions, functions, procedures, proposals, methods, and/or operational flowcharts disclosed in this document.

The one or more processors 102 and 202 may be referred to as controllers, microcontrollers, microprocessors, or microcomputers. The one or more processors 102 and 202 may be implemented by hardware, firmware, software, or a combination thereof. As an example, one or more Application Specific Integrated Circuits (ASICs), one or more Digital Signal Processors (DSPs), one or more Digital Signal Processing Devices (DSPDs), one or more Programmable Logic Devices (PLDs), or one or more Field Programmable Gate Arrays (FPGAs) may be included in the one or more processors 102 and 202. The descriptions, functions, procedures, proposals, methods, and/or operational flowcharts disclosed in this document may be implemented using firmware or software and the firmware or software may be configured to include the modules, procedures, or functions. Firmware or software configured to perform the descriptions, functions, procedures, proposals, methods, and/or operational flowcharts disclosed in this document may be included in the one or more processors 102 and 202 or stored in the one or more memories 104 and 204 so as to be driven by the one or more processors 102 and 202. The descriptions, functions, procedures, proposals, methods, and/or operational flowcharts disclosed in this document may be implemented using firmware or software in the form of code, commands, and/or a set of commands.

The one or more memories 104 and 204 may be connected to the one or more processors 102 and 202 and store various types of data, signals, messages, information, programs, code, instructions, and/or commands. The one or more memories 104 and 204 may be configured by Read-Only Memories (ROMs), Random Access Memories (RAMs), Electrically Erasable Programmable Read-Only Memories (EPROMs), flash memories, hard drives, registers, cash memories, computer-readable storage media, and/or combinations thereof. The one or more memories 104 and 204 may be located at the interior and/or exterior of the one or more processors 102 and 202. The one or more memories 104 and 204 may be connected to the one or more processors 102 and 202 through various technologies such as wired or wireless connection.

The one or more transceivers 106 and 206 may transmit user data, control information, and/or radio signals/channels, mentioned in the methods and/or operational flowcharts of this document, to one or more other devices. The one or more transceivers 106 and 206 may receive user data, control information, and/or radio signals/channels, mentioned in the descriptions, functions, procedures, proposals, methods, and/or operational flowcharts disclosed in this document, from one or more other devices. For example, the one or more transceivers 106 and 206 may be connected to the one or more processors 102 and 202 and transmit and receive radio signals. For example, the one or more processors 102 and 202 may perform control so that the one or more transceivers 106 and 206 may transmit user data, control information, or radio signals to one or more other devices. The one or more processors 102 and 202 may perform control so that the one or more transceivers 106 and 206 may receive user data, control information, or radio signals from one or more other devices. The one or more transceivers 106 and 206 may be connected to the one or more antennas 108 and 208 and the one or more transceivers 106 and 206 may be configured to transmit and receive user data, control information, and/or radio signals/channels, mentioned in the descriptions, functions, procedures, proposals, methods, and/or operational flowcharts disclosed in this document, through the one or more antennas 108 and 208. In this document, the one or more antennas may be a plurality of physical antennas or a plurality of logical antennas (e.g., antenna ports). The one or more transceivers 106 and 206 may convert received radio signals/channels etc. from RF band signals into baseband signals in order to process received user data, control information, radio signals/channels, etc. using the one or more processors 102 and 202. The one or more transceivers 106 and 206 may convert the user data, control information, radio signals/channels, etc. processed using the one or more processors 102 and 202 from the base band signals into the RF band signals. To this end, the one or more transceivers 106 and 206 may include (analog) oscillators and/or filters.

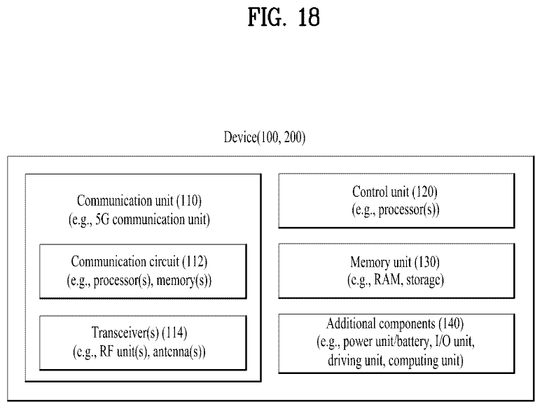

FIG. 18 illustrates another example of a wireless device applied to the present disclosure. The wireless device may be implemented in various forms according to a use-case/service (refer to FIG. 25)

Referring to FIG. 18, wireless devices 100 and 200 may correspond to the wireless devices 100 and 200 of FIG. 17 and may be configured by various elements, components, units/portions, and/or modules. For example, each of the wireless devices 100 and 200 may include a communication unit 110, a control unit 120, a memory unit 130, and additional components 140. The communication unit may include a communication circuit 112 and transceiver(s) 114. For example, the communication circuit 112 may include the one or more processors 102 and 202 and/or the one or more memories 104 and 204 of FIG. 16. For example, the transceiver(s) 114 may include the one or more transceivers 106 and 206 and/or the one or more antennas 108 and 208 of FIG. 16. The control unit 120 is electrically connected to the communication unit 110, the memory 130, and the additional components 140 and controls overall operation of the wireless devices. For example, the control unit 120 may control an electric/mechanical operation of the wireless device based on programs/code/commands/information stored in the memory unit 130. The control unit 120 may transmit the information stored in the memory unit 130 to the exterior (e.g., other communication devices) via the communication unit 110 through a wireless/wired interface or store, in the memory unit 130, information received through the wireless/wired interface from the exterior (e.g., other communication devices) via the communication unit 110.

The additional components 140 may be variously configured according to types of wireless devices. For example, the additional components 140 may include at least one of a power unit/battery, input/output (I/O) unit, a driving unit, and a computing unit. The wireless device may be implemented in the form of, without being limited to, the robot (100a of FIG. 16), the vehicles (100b-1 and 100b-2 of FIG. 16), the XR device (100c of FIG. 16), the hand held device (100d of FIG. 16), the home appliance (100e of FIG. 16), the IoT device (100f of FIG. 16), a digital broadcast terminal, a hologram device, a public safety device, an MTC device, a medicine device, a fintech device (or a finance device), a security device, a climate/environment device, the AI server/device (400 of FIG. 16), the BSs (200 of FIG. 16), a network node, etc. The wireless device may be used in a mobile or fixed place according to a use-example/service.

In FIG. 18, the entirety of the various elements, components, units/portions, and/or modules in the wireless devices 100 and 200 may be connected to each other through a wired interface or at least a part thereof may be wirelessly connected through the communication unit 110. For example, in each of the wireless devices 100 and 200, the control unit 120 and the communication unit 110 may be connected by wire and the control unit 120 and first units (e.g., 130 and 140) may be wirelessly connected through the communication unit 110. Each element, component, unit/portion, and/or module within the wireless devices 100 and 200 may further include one or more elements. For example, the control unit 120 may be configured by a set of one or more processors. As an example, the control unit 120 may be configured by a set of a communication control processor, an application processor, an Electronic Control Unit (ECU), a graphical processing unit, and a memory control processor. As another example, the memory 130 may be configured by a Random Access Memory (RAM), a Dynamic RAM (DRAM), a Read Only Memory (ROM)), a flash memory, a volatile memory, a non-volatile memory, and/or a combination thereof.

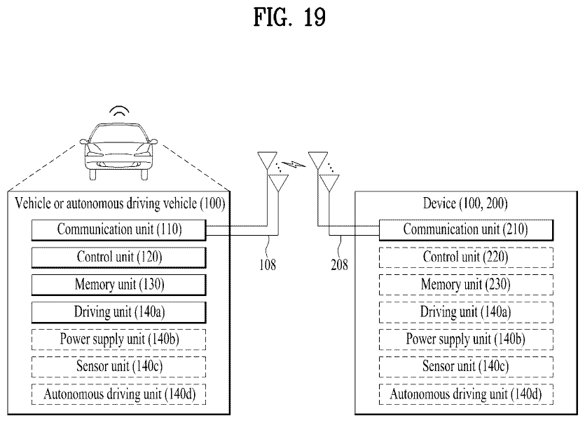

FIG. 19 illustrates a vehicle or an autonomous driving vehicle applied to the present disclosure. The vehicle or autonomous driving vehicle may be implemented by a mobile robot, a car, a train, a manned/unmanned Aerial Vehicle (AV), a ship, etc.

Referring to FIG. 19, a vehicle or autonomous driving vehicle 100 may include an antenna unit 108, a communication unit 110, a control unit 120, a driving unit 140a, a power supply unit 140b, a sensor unit 140c, and an autonomous driving unit 140d. The antenna unit 108 may be configured as a part of the communication unit 110. The blocks 110/130/140a to 140d correspond to the blocks 110/130/140 of FIG. 18, respectively.

The communication unit 110 may transmit and receive signals (e.g., data and control signals) to and from external devices such as other vehicles, BSs (e.g., gNBs and road side units), and servers. The control unit 120 may perform various operations by controlling elements of the vehicle or the autonomous driving vehicle 100. The control unit 120 may include an Electronic Control Unit (ECU). Also, the driving unit 140a may cause the vehicle or the autonomous driving vehicle 100 to drive on a road. The driving unit 140a may include an engine, a motor, a powertrain, a wheel, a brake, a steering device, etc. The power supply unit 140b may supply power to the vehicle or the autonomous driving vehicle 100 and include a wired/wireless charging circuit, a battery, etc. The sensor unit 140c may acquire a vehicle state, ambient environment information, user information, etc. The sensor unit 140c may include an Inertial Measurement Unit (IMU) sensor, a collision sensor, a wheel sensor, a speed sensor, a slope sensor, a weight sensor, a heading sensor, a position module, a vehicle forward/backward sensor, a battery sensor, a fuel sensor, a tire sensor, a steering sensor, a temperature sensor, a humidity sensor, an ultrasonic sensor, an illumination sensor, a pedal position sensor, etc. The autonomous driving unit 140d may implement technology for maintaining a lane on which a vehicle is driving, technology for automatically adjusting speed, such as adaptive cruise control, technology for autonomously driving along a determined path, technology for driving by automatically setting a path if a destination is set, and the like.

For example, the communication unit 110 may receive map data, traffic information data, etc. from an external server. The autonomous driving unit 140d may generate an autonomous driving path and a driving plan from the acquired data. The control unit 120 may control the driving unit 140a such that the vehicle or the autonomous driving vehicle 100 may move along the autonomous driving path according to the driving plan (e.g., speed/direction control). In the middle of autonomous driving, the communication unit 110 may aperiodically/periodically acquire recent traffic information data from the external server and acquire surrounding traffic information data from neighboring vehicles. In the middle of autonomous driving, the sensor unit 140c may obtain a vehicle state and/or surrounding environment information. The autonomous driving unit 140d may update the autonomous driving path and the driving plan based on the newly acquired data/information. The communication unit 110 may transfer information about a vehicle position, the autonomous driving path, and/or the driving plan to the external server. The external server may predict traffic information data using AI technology, etc., based on the information collected from vehicles or autonomous driving vehicles and provide the predicted traffic information data to the vehicles or the autonomous driving vehicles.

The embodiments described above are those in which components and features of the present disclosure are combined in a predetermined form. Each component or feature should be considered optional unless explicitly stated otherwise. Each component or feature may be implemented in a form that is not combined with other components or features. In addition, it is also possible to constitute an embodiment of the present disclosure by combining some components and/or features. The order of operations described in the embodiments of the present disclosure may be changed. Some configurations or features of one embodiment may be included in other embodiments, or may be replaced with corresponding configurations or features of other embodiments. It is obvious that the embodiments may be configured by combining claims that do not have an explicit citation relationship in the claims or may be included as new claims by amendment after filing.

As described before, a detailed description has been given of preferred embodiments of the present disclosure so that those skilled in the art may implement and perform the present disclosure. While reference has been made above to the preferred embodiments of the present disclosure, those skilled in the art will understand that various modifications and alterations may be made to the present disclosure within the scope of the present disclosure. For example, those skilled in the art may use the components described in the foregoing embodiments in combination. The above embodiments are therefore to be construed in all aspects as illustrative and not restrictive. The scope of the disclosure should be determined by the appended claims and their legal equivalents, not by the above description, and all changes coming within the meaning and equivalency range of the appended claims are intended to be embraced therein.

### INDUSTRIAL APPLICABILITY

The disclosure may be used in a terminal, base station, or other equipment of a wireless mobile communication system.

1. A method of transmitting a signal by a transmission device in a communication system, the method comprising:
generating a first encoded bit sequence from an information bit sequence, based on a polar code;
generating a second encoded bit sequence by puncturing the first encoded bit sequence based on a code rate; and
transmitting the second encoded bit sequence,
wherein the first encoded bit sequence is implemented based on a puncturing pattern including the following structure, and the puncturing pattern satisfies a nested property,

| | Puncturing pattern (number of punctured bits: 122) |
|---|---|
| (512, 256) | 1, 2, 3, 4, 5, 6, 7, 8, 9, 10, 11, 12, 13, 14, 15, 16, 17, 18, 19, 20, 21, 22, 23, 24, 25, |
| Polar code | 26, 27, 29, 33, 34, 35, 36, 37, 38, 39, 41, 42, 43, 45, 49, 50, 51, 53, 65, 66, 67, 68, |
| | 69, 70, 71, 73, 74, 75, 77, 81, 82, 97, 129, 130, 131, 132, 133, 134, 137, 145, 161, |
| | 257, 258, 259, 260, 261, 262, 265, 273, 289, 32, 28, 30, 31, 40, 44, 46, 52, 72, |
| | 47, 54, 55, 76, 78, 79, 48, 88, 136, 58, 84, 86, 90, 59, 61, 144, 104, 180, 122, 87, |
| | 100, 102, 103, 106, 114, 200, 57, 83, 85, 89, 98, 99, 101, 135, 138, 139, 141, 146 |

2. The method of claim 1, wherein the puncturing pattern includes the following,

| | Puncturing pattern (number of punctured bits: 164) |
|---|---|
| (512, 256) | 1, 2, 3, 4, 5, 6, 7, 8, 9, 10, 11, 12, 13, 14, 15, 16, 17, 18, 19, 20, 21, 22, 23, 24, 25, |
| Polar code | 26, 27, 29, 33, 34, 35, 36, 37, 38, 39, 41, 42, 43, 45, 49, 50, 51, 53, 65, 66, 67, 68, |
| | 69, 70, 71, 73, 74, 75, 77, 81, 82, 97, 129, 130, 131, 132, 133, 134, 137, 145, 161, |
| | 257, 258, 259, 260, 261, 262, 265, 273, 289, 32, 28, 30, 31, 40, 44, 46, 52, 72, |
| | 47, 54, 55, 76, 78, 79, 48, 88, 136, 58, 84, 86, 90, 59, 61, 144, 104, 180, 122, 87, |
| | 100, 102, 103, 106, 114, 200, 57, 83, 85, 89, 98, 99, 101, 135, 138, 139, 141, |
| | 146, 147, 149, 153, 162, 163, 165, 63, 158, 92, 110, 140, 142, 148, 164, 91, 93, |
| | 119, 105, 113, 150, 143, 151, 154, 155, 157, 280, 229, 194, 195, 197, 172, 264, |
| | 299, 309, 333, 276, 272, 193, 263, 266, 267, 269 |

3. The method of claim 2, wherein the puncturing pattern includes the following,

| | Puncturing pattern (number of punctured bits: 205) |
|---|---|
| (512, 256) | 1, 2, 3, 4, 5, 6, 7, 8, 9, 10, 11, 12, 13, 14, 15, 16, 17, 18, 19, 20, 21, 22, 23, 24, 25, |
| Polar code | 26, 27, 29, 33, 34, 35, 36, 37, 38, 39, 41, 42, 43, 45, 49, 50, 51, 53, 65, 66, 67, 68, |
| | 69, 70, 71, 73, 74, 75, 77, 81, 82, 97, 129, 130, 131, 132, 133, 134, 137, 145, 161, |
| | 257, 258, 259, 260, 261, 262, 265, 273, 289, 32, 28, 30, 31, 40, 44, 46, 52, 72, |
| | 47, 54, 55, 76, 78, 79, 48, 88, 136, 58, 84, 86, 90, 59, 61, 144, 104, 180, 122, 87, |
| | 100, 102, 103, 106, 114, 200, 57, 83, 85, 89, 98, 99, 101, 135, 138, 139, 141, |
| | 146, 147, 149, 153, 162, 163, 165, 63, 158, 92, 110, 140, 142, 148, 164, 91, 93, |
| | 119, 105, 113, 150, 143, 151, 154, 155, 157, 280, 229, 194, 195, 197, 172, 264, |
| | 299, 309, 333, 276, 272, 193, 263, 266, 267, 269, 274, 115, 169, 177, 159, |
| | 118, 170, 108, 270, 95, 109, 331, 279, 275, 277, 290, 291, 293, 166, 329, 179, |
| | 278, 298, 305, 196, 199, 217, 174, 60, 173, 324, 283, 390, 321, 209, 152, 117, |
| | 198, 295, 201, 322 |

4. A transmission device used in a communication system, comprising:
at least one radio frequency (RF) unit;
at least one processor; and
at least one computer memory operably connected to the at least one processor, and when executed, causing the at least one processor to perform operations,
wherein the operations include:
generating a first encoded bit sequence from an information bit sequence, based on a polar code;
generating a second encoded bit sequence by puncturing the first encoded bit sequence based on a code rate; and
transmitting the second encoded bit sequence, and
wherein the first encoded bit sequence is implemented based on a puncturing pattern including the following structure, and the puncturing pattern satisfies a nested property,

| | Puncturing pattern (number of punctured bits: 122) |
|---|---|
| (512, 256) | 1, 2, 3, 4, 5, 6, 7, 8, 9, 10, 11, 12, 13, 14, 15, 16, 17, 18, 19, 20, 21, 22, 23, 24, 25, |
| Polar code | 26, 27, 29, 33, 34, 35, 36, 37, 38, 39, 41, 42, 43, 45, 49, 50, 51, 53, 65, 66, 67, 68, |
| | 69, 70, 71, 73, 74, 75, 77, 81, 82, 97, 129, 130, 131, 132, 133, 134, 137, 145, 161, |
| | 257, 258, 259, 260, 261, 262, 265, 273, 289, 32, 28, 30, 31, 40, 44, 46, 52, 72, |
| | 47, 54, 55, 76, 78, 79, 48, 88, 136, 58, 84, 86, 90, 59, 61, 144, 104, 180, 122, 87, |
| | 100, 102, 103, 106, 114, 200, 57, 83, 85, 89, 98, 99, 101, 135, 138, 139, 141, 146 |

5. The transmission device of claim 4, wherein the puncturing pattern includes the following,

| | Puncturing pattern (number of punctured bits: 164) |
|---|---|
| (512, 256) | 1, 2, 3, 4, 5, 6, 7, 8, 9, 10, 11, 12, 13, 14, 15, 16, 17, 18, 19, 20, 21, 22, 23, 24, 25, |
| Polar code | 26, 27, 29, 33, 34, 35, 36, 37, 38, 39, 41, 42, 43, 45, 49, 50, 51, 53, 65, 66, 67, 68, |
| | 69, 70, 71, 73, 74, 75, 77, 81, 82, 97, 129, 130, 131, 132, 133, 134, 137, 145, 161, |
| | 257, 258, 259, 260, 261, 262, 265, 273, 289, 32, 28, 30, 31, 40, 44, 46, 52, 72, |
| | 47, 54, 55, 76, 78, 79, 48, 88, 136, 58, 84, 86, 90, 59, 61, 144, 104, 180, 122, 87, |
| | 100, 102, 103, 106, 114, 200, 57, 83, 85, 89, 98, 99, 101, 135, 138, 139, 141, |
| | 146, 147, 149, 153, 162, 163, 165, 63, 158, 92, 110, 140, 142, 148, 164, 91, 93, |
| | 119, 105, 113, 150, 143, 151, 154, 155, 157, 280, 229, 194, 195, 197, 172, 264, |
| | 299, 309, 333, 276, 272, 193, 263, 266, 267, 269 |

6. The transmission device of claim 5, wherein the puncturing pattern includes the following,

| | Puncturing pattern (number of punctured bits: 205) |
|---|---|
| (512, 256) | 1, 2, 3, 4, 5, 6, 7, 8, 9, 10, 11, 12, 13, 14, 15, 16, 17, 18, 19, 20, 21, 22, 23, 24, 25, |
| Polar code | 26, 27, 29, 33, 34, 35, 36, 37, 38, 39, 41, 42, 43, 45, 49, 50, 51, 53, 65, 66, 67, 68, |
| | 69, 70, 71, 73, 74, 75, 77, 81, 82, 97, 129, 130, 131, 132, 133, 134, 137, 145, 161, |
| | 257, 258, 259, 260, 261, 262, 265, 273, 289, 32, 28, 30, 31, 40, 44, 46, 52, 72, |
| | 47, 54, 55, 76, 78, 79, 48, 88, 136, 58, 84, 86, 90, 59, 61, 144, 104, 180, 122, 87, |
| | 100, 102, 103, 106, 114, 200, 57, 83, 85, 89, 98, 99, 101, 135, 138, 139, 141, |
| | 146, 147, 149, 153, 162, 163, 165, 63, 158, 92, 110, 140, 142, 148, 164, 91, 93, |
| | 119, 105, 113, 150, 143, 151, 154, 155, 157, 280, 229, 194, 195, 197, 172, 264, |
| | 299, 309, 333, 276, 272, 193, 263, 266, 267, 269, 274, 115, 169, 177, 159, 118, |
| | 170, 108, 270, 95, 109, 331, 279, 275, 277, 290, 291, 293, 166, 329, 179, 278, |
| | 298, 305, 196, 199, 217, 174, 60, 173, 324, 283, 390, 321, 209, 152, 117, 198, |
| | 295, 201, 322 |

7-9. (canceled)

10. A computer-readable storage medium including at least one computer program which when executed, causes at least one processor to perform operations,
wherein the operations include:
generating a first encoded bit sequence from an information bit sequence, based on a polar code;
generating a second encoded bit sequence by puncturing the first encoded bit sequence based on a code rate; and
transmitting the second encoded bit sequence, and
wherein the first encoded bit sequence is implemented based on a puncturing pattern including the following structure, and the puncturing pattern satisfies a nested property,

| | Puncturing pattern (number of punctured bits: 122) |
|---|---|
| (512, 256) | 1, 2, 3, 4, 5, 6, 7, 8, 9, 10, 11, 12, 13, 14, 15, 16, 17, 18, 19, 20, 21, 22, 23, 24, 25, |
| Polar code | 26, 27, 29, 33, 34, 35, 36, 37, 38, 39, 41, 42, 43, 45, 49, 50, 51, 53, 65, 66, 67, 68, |
| | 69, 70, 71, 73, 74, 75, 77, 81, 82, 97, 129, 130, 131, 132, 133, 134, 137, 145, 161, |
| | 257, 258, 259, 260, 261, 262, 265, 273, 289, 32, 28, 30, 31, 40, 44, 46, 52, 72, |
| | 47, 54, 55, 76, 78, 79, 48, 88, 136, 58, 84, 86, 90, 59, 61, 144, 104, 180, 122, 87, |
| | 100, 102, 103, 106, 114, 200, 57, 83, 85, 89, 98, 99, 101, 135, 138, 139, 141, 146 |

11. The computer-readable storage medium of claim 10, wherein the puncturing pattern includes the following,

| | Puncturing pattern (number of punctured bits: 164) |
|---|---|
| (512, 256) | 1, 2, 3, 4, 5, 6, 7, 8, 9, 10, 11, 12, 13, 14, 15, 16, 17, 18, 19, 20, 21, 22, 23, 24, 25, |
| Polar code | 26, 27, 29, 33, 34, 35, 36, 37, 38, 39, 41, 42, 43, 45, 49, 50, 51, 53, 65, 66, 67, 68, |
| | 69, 70, 71, 73, 74, 75, 77, 81, 82, 97, 129, 130, 131, 132, 133, 134, 137, 145, 161, |
| | 257, 258, 259, 260, 261, 262, 265, 273, 289, 32, 28, 30, 31, 40, 44, 46, 52, 72, |
| | 47, 54, 55, 76, 78, 79, 48, 88, 136, 58, 84, 86, 90, 59, 61, 144, 104, 180, 122, 87, |
| | 100, 102, 103, 106, 114, 200, 57, 83, 85, 89, 98, 99, 101, 135, 138, 139, 141, |
| | 146, 147, 149, 153, 162, 163, 165, 63, 158, 92, 110, 140, 142, 148, 164, 91, 93, |
| | 119, 105, 113, 150, 143, 151, 154, 155, 157, 280, 229, 194, 195, 197, 172, 264, |
| | 299, 309, 333, 276, 272, 193, 263, 266, 267, 269 |

12. The computer-readable storage medium of claim 11, wherein the puncturing pattern includes the following,

| | Puncturing pattern (number of punctured bits: 205) |
|---|---|
| (512, 256) | 1, 2, 3, 4, 5, 6, 7, 8, 9, 10, 11, 12, 13, 14, 15, 16, 17, 18, 19, 20, 21, 22, 23, 24, 25, |
| Polar code | 26, 27, 29, 33, 34, 35, 36, 37, 38, 39, 41, 42, 43, 45, 49, 50, 51, 53, 65, 66, 67, 68, |
| | 69, 70, 71, 73, 74, 75, 77, 81, 82, 97, 129, 130, 131, 132, 133, 134, 137, 145, 161, |
| | 257, 258, 259, 260, 261, 262, 265, 273, 289, 32, 28, 30, 31, 40, 44, 46, 52, 72, |
| | 47, 54, 55, 76, 78, 79, 48, 88, 136, 58, 84, 86, 90, 59, 61, 144, 104, 180, 122, 87, |
| | 100, 102, 103, 106, 114, 200, 57, 83, 85, 89, 98, 99, 101, 135, 138, 139, 141, |
| | 146, 147, 149, 153, 162, 163, 165, 63, 158, 92, 110, 140, 142, 148, 164, 91, 93, |
| | 119, 105, 113, 150, 143, 151, 154, 155, 157, 280, 229, 194, 195, 197, 172, 264, |
| | 299, 309, 333, 276, 272, 193, 263, 266, 267, 269, 274, 115, 169, 177, 159, |
| | 118, 170, 108, 270, 95, 109, 331, 279, 275, 277, 290, 291, 293, 166, 329, 179, |
| | 278, 298, 305, 196, 199, 217, 174, 60, 173, 324, 283, 390, 321, 209, 152, 117, |
| | 198, 295, 201, 322 |
